(19) United States
(12) Patent Application Publication
(10) Pub. No.: US 2011/0226518 A1
(43) Pub. Date: Sep. 22, 2011

(54) SUBSTRATE OF CIRCUIT MODULE AND MANUFACTURING METHOD THEREFOR

(76) Inventor: Risato Ohhira, Tokyo (JP)

(21) Appl. No.: 13/130,675

(22) PCT Filed: Nov. 24, 2009
(86) PCT No.: PCT/JP2009/006329

§ 371 Date: May 23, 2011

(30) Foreign Application Priority Data
Nov. 26, 2008 (JP) 2008-300278
May 12, 2009 (JP) 2009-115879

(51) Int. Cl. H05K 1/11; H05K 3/02

(52) U.S. Cl. 174/261; 29/847

(57) ABSTRACT

A coplanar line formed on a high-frequency substrate of a high-frequency module includes a first dielectric layer, a signal line which is formed on the surface of the first dielectric layer and connected to a core line of a coaxial connector, a ground which is formed in opposite areas beside the signal line with a clearance therebetween, and a lower ground of the first dielectric layer. A second dielectric layer is laminated with the first dielectric layer so as to interpose the lower ground therebetween. Additionally, the lower ground is exposed on the terminal face of the high-frequency substrate coupled with the coaxial connector in either the first dielectric layer or the second dielectric layer and connected to an outer conductor of the coaxial connector. Thus, it is possible to prevent an insertion loss from increasing due to electromagnetic emission occurring in the clearance of the high-frequency substrate in response to transmitting signals in a high frequency range.

### TECHNICAL FIELD

This invention relates to substrates of circuit modules including coaxial connectors and manufacturing methods therefor, and in particularly to joint structures for substrates, including transmission lines, and coaxial connectors.

This invention claims priority on Japanese Patent Application No. 2008-300278 filed on Nov. 26, 2008 and Japanese Patent Application No. 2009-115879 filed on May 12, 2009, the entire content of which is incorporated herein by reference.

### BACKGROUND ART

Various functional circuits (e.g. amplifier circuits, multiplexing circuits, isolation circuits) are fabricated into integrated circuits (IC) and stored in individual modules (or packages) serving as IC modules (or circuit modules), which are adopted in electronic circuits. Coaxial connectors are used as input/output terminals of high-frequency signals of circuit modules. When circuit modules employ ball grid arrays (BGA) as input/output terminals of high-frequency signals, circuit modules need to be electrically connected to printed-circuit boards, in which wiring patterns are connected to coaxial connectors, before being connected with measuring instruments used for performance evaluation.

Patent Document 1 discloses “a circuit module including a coaxial connector”, which employs a joint structure of a high-frequency transmission line and a coaxial connector as shown in FIGS. 71 and 72. FIG. 71 is a perspective view showing the structure of a circuit module, and FIG. 72 is a cross-sectional view taken along line B-B juxtaposed to transmission signals.

The above joint structure is configured of a coaxial connector, including a dielectric member 90, a core line 80 serving as an inner conductor and an outer conductor (a module base) 70, and a multilayered circuit substrate 40 in which a signal line 10 corresponding to a coplanar line constitutes a surface layer pattern. The multilayered circuit substrate 40 shown in FIG. 72 is a multilayered circuit substrate having three or more layers, in which a ground 20 (a first layer) and a ground 50 (a second layer), disposed on opposite sides of a coplanar line, is connected with a conductor 21 composed of a plating on the terminal face of a substrate.

Mismatching may easily occur at the joint section, between the coaxial connector and the coplanar line or the microstrip line, due to their different line structures. As a result, reflection may easily occur as frequency becomes higher, wherein an insertion loss increases as reflection increases.

Patent Document 1 teaches that a distance 20a between the grounds 20 constituting the coplanar line is shorter than a diameter 70a of a dielectric member 90 constituting the coaxial connector. Additionally, the grounds 20, 50 constituting the coplanar line are connected to a conductor 21 at the terminal face of the substrate, whilst the ground 20 is electrically connected to the outer conductor 70 of the coaxial connector via a solder 23. This constitution reduces impedance between the outer conductor (or ground) 70 of the coaxial connector and the ground 20 of the coplanar line, thus improving the reflection characteristics.

Patent Document 2 discloses “a high-frequency connector with a flange”, which demonstrates a joint structure for a high-frequency transmission line and a coaxial connector as shown in FIG. 73. FIG. 73 is a perspective view. The joint structure of the high-frequency transmission line and the coaxial connector is configured of the coaxial connector, including the core line 80 serving as the inner conductor and the outer conductor 70, and the coplanar line including the signal line 10 and the grounds 20 on opposite sides.

Mismatching may easily occur at the joint section, between the coaxial connector and the coplanar line or the microstrip line, due to their different line structures. As a result, reflection may easily occur as the frequency becomes higher, wherein insertion loss may increase as reflection increases.

For this reason, an outer conductor ground-reinforcing pin 70f, in which the core line 80 serving as the inner conductor is unified with the outer conductor 70, are brought into contact with the signal line 10 constituting the coplanar line and the grounds 20.

### PRIOR ART DOCUMENTS

### Patent Documents

Patent Document 1: Japanese Patent Application Publication No. H10-327004
Patent Document 2: Japanese Patent Application Publication No. 2001-52819

### SUMMARY OF THE INVENTION

### Problems to be Solved by the Invention

Patent Document 1 suffers from the following problem.

Since the ground 20 of the coplanar line is electrically connected to the outer conductor 70 of the coaxial connector via the solder 70, a clearance (or an air gap), corresponding to the applied thickness of the solder 23, may be formed between the outer conductor 70 of the coaxial connector and the second-layer ground 50 constituting the coplanar line beneath the core line 80 of the coaxial connector.

Even when only the ground 20 of the coplanar line (i.e. the surface layer ground) is electrically connected to the outer conductor 70 of the coaxial connector, it is difficult to completely eliminate the clearance between the outer conductor 70 of the coaxial connector and the second-layer ground 50 of the coplanar line beneath the core line 80 of the coaxial connector due to manufacturing error. Even when a good electric connection is secured between the ground 20 and the outer conductor 70 of the coaxial connector whilst the ground 20 is closely juxtaposed to the outer conductor 70 of the coaxial connector, it is difficult to reduce the scale of a clearance, in a direction perpendicular to a signal transmitting direction, formed between the outer conductor 70 of the coaxial connector and the ground 50 of the coplanar line.

As signals are transmitted at higher frequencies, a part of transmitting signals tends to emanate from the clearance between the outer conductor 70 and the ground 50 beneath the core line 80 of the coaxial connector, thus increasing insertion loss.

Patent Document 2 suffers from the following problem.

Since the coplanar line and the coaxial connector come in contact with each other on their upper sides, it is difficult to electrically connect the outer conductor 70 of the coaxial connector to the second-layer (or internal-layer) conductor (which is not shown in FIG. 73 but equivalent to the ground 50 in FIG. 72) beneath the core line 80 of the coaxial connector. Even when an electrical contact is established between the outer conductor 70 of the coaxial connector and the second-layer conductor of the coplanar line by completely eliminating the clearance therebetween, it is difficult to maintain the electric contact therebetween due to mechanical stress and thermal stress. Even when the ground 20 (i.e. the surface layer ground) is electrically connected to the outer conductor 70 of the coaxial connector whilst the ground 20 is closely juxtaposed to the outer conductor 70 of the coaxial connector, it is difficult to reduce the scale of a clearance in a direction perpendicular to a signal transmitting direction in the clearance between the outer conductor 70 of the coaxial connector and the conductor of the coplanar line. As signals are transmitted at higher frequencies, a part of transmitting signals tends to emanate from the clearance between the outer conductor 70 and the conductor beneath the core line 80 serving as the inner conductor of the coaxial connector, thus increasing insertion loss.

It is an object of this invention to provide a substrate of a circuit module and a manufacturing method for preventing an insertion loss from increasing due to electromagnetic emission. That is, a first object is to prevent an insertion loss from increasing due to electromagnetic emission in a high-frequency range, whilst a second object is to prevent insertion loss from increasing due to reflection.

### Means for Solving the Problems

This invention relates to a high-frequency substrate including a coplanar line coupled with a coaxial connector. The coplanar line further includes a first dielectric layer, a signal line that is formed on the surface of the first dielectric layer and connected to an inner conductor of the coaxial connector, a first ground that is formed in opposite areas beside the signal line with a clearance distant from the signal line, and a second ground that is formed on the backside of the first dielectric layer. A second dielectric layer is laminated with the first dielectric layer so as to interpose the second ground therebetween. The second ground is exposed in a predetermined area of the first dielectric layer, so that the exposed portion of the second ground is connected to an outer conductor of the coaxial connector.

This invention relates to a high-frequency module including a high-frequency substrate having a coplanar line coupled with a coaxial connector. The coplanar line further includes a first dielectric layer, a signal line that is formed on the surface of the first dielectric layer and connected to an inner conductor of the coaxial connector, a first ground that is formed in opposite areas beside the signal line with a clearance distant from the signal line, and a second ground that is formed on the backside of the first dielectric layer. A second dielectric layer is laminated with the first dielectric layer so as to interpose the second ground therebetween. The second ground is exposed in a predetermined area of the first dielectric layer, so that the exposed portion of the second ground is connected to an outer conductor of the coaxial connector.

Furthermore, this invention relates to a manufacturing method of a high-frequency substrate including a coplanar line coupled with a coaxial connector. A second conductive layer, a first dielectric layer, and a first conductive layer are sequentially formed on a second dielectric layer; the first conductive layer and the first dielectric layer are selective removed so as to expose a predetermined area of the second conductive layer; the first conductive layer is selectively removed so as to form a signal line coupled with the coaxial connector on the first dielectric layer; subsequently, a ground is formed on a terminal face coupled with the coaxial connector in opposite areas beside the signal line with a clearance distant from the signal line; thus, the coplanar line including the signal line, the ground, and the second dielectric layer is formed.

Alternatively, in the manufacturing method of a high-frequency substrate including a coplanar line coupled with a coaxial connector, a second conductive layer, a first dielectric layer, and a first conductive layer are sequentially formed on a second dielectric layer; the second dielectric layer is selectively removed so as to expose the second conductive layer in opposite areas beside the signal line at a terminal face coupled with the coaxial connector; the first conductive layer is selective removed so as to form a signal line coupled with an inner conductor of the coaxial connector on the first dielectric layer; subsequently, a ground is formed in the opposite areas beside the signal line with a clearance distant from the signal line; thus, the coplanar line including the signal line, the second conductive layer, and the ground is formed.

### Effects of the Invention

This invention is able to suppress frequency components of transmitting signals from being electromagnetically emitted from a clearance surrounded by the outer conductor, the lower ground and the conductive members when signals are transmitted from the coplanar line to the coaxial connector or from the coaxial connector to the coplanar line since the exposed portion of the lower ground of the coplanar line is securely connected to the outer conductor of the coaxial connector via the conductive members. Additionally, this invention is able to suppress electromagnetic emission in a desired frequency range from a clearance between the outer conductor and the lower ground; hence, it is possible to reduce insertion loss due to electromagnetic emission.

Additionally, the conductive members, by which the exposed portion of the lower ground of the coplanar line is electrically connected to the outer conductor of the coaxial connector, are formed continuously from the extension line of the lower ground at the contact section with the outer conductor, wherein they are raised at the height higher than the center position of the core line of the coaxial connector. Since the ground structure gradually varies in the direction from the lower ground to the outer conductor, it is possible to alleviate significant variations of electric field distribution at the joint section between the coplanar line and the coaxial connector when signals are transmitted from the coplanar line to the coaxial connector or from the coaxial connector to the coplanar line; thus, it is possible to improve reflection characteristics of the high-frequency substrate. By improving reflection characteristics, it is possible to reduce insertion loss due to electromagnetic emission.

### BRIEF DESCRIPTION OF THE DRAWINGS

FIG. 1 A top view for explaining the basic principle of a circuit module and a substrate of this invention.

FIG. 2 A cross-sectional view taken along line X-X in FIG. 1.

FIG. 3 A top view of a high-frequency module and a substrate according to Embodiment 1 of this invention.

FIG. 4 A cross-sectional view taken along line X-X in FIG. 3.

FIG. 5 A cross-sectional view taken along line Y-Y in FIG. 3.

FIG. 6 A cross-sectional view taken along line Z-Z in FIG. 3.

FIG. 7 Side views for explaining a manufacturing method of a high-frequency substrate according to Embodiment 1.

FIG. 8 A graph for demonstrating an improved effect of insertion loss characteristics according to Embodiment 1 compared to a comparative example.

FIG. 9 A top view of a high-frequency module and a substrate according to Embodiment 2 of this invention.

FIG. 10 A cross-sectional view taken in line X-X in FIG. 9.

FIG. 11 A cross-sectional view taken in line Y-Y in FIG. 9.

FIG. 12 A cross-sectional view taken in line Z-Z in FIG. 9.

FIG. 13 A back view of the high-frequency module and the substrate according to Embodiment 2.

FIG. 14 Side views for explaining a manufacturing method of a high-frequency substrate according to Embodiment 2.

FIG. 15 A graph for demonstrating an improved effect of insertion loss characteristics according to Embodiment 2 compared to a comparative example.

FIG. 16 A top view of a high-frequency module and a substrate according to Embodiment 3 of this invention.

FIG. 17 A cross-sectional view taken along line X-X in FIG. 16.

FIG. 18 A cross-sectional view taken along line Y-Y in FIG. 16.

FIG. 19 A cross-sectional view taken along line Z-Z in FIG. 16.

FIG. 20 A graph for demonstrating an improved effect of insertion loss characteristics according to Embodiment 3 compared to Embodiment 1 and a comparative example.

FIG. 21 A top view of a high-frequency module and a substrate according to Embodiment 4 of this invention.

FIG. 22 A cross-sectional view taken along line X-X in FIG. 21.

FIG. 23 A cross-sectional view taken along line Y-Y in FIG. 21.

FIG. 24 A cross-sectional view taken along line Z-Z in FIG. 21.

FIG. 25 A back view of a high-frequency module and a substrate according to Embodiment 4.

FIG. 26 A graph for demonstrating an improved effect of insertion loss characteristics according to Embodiment 4 compared to Embodiment 2 and a comparative example.

FIG. 27 A top view of a high-frequency transmission line and a substrate according to Embodiment 5 of this invention.

FIG. 28 A top view of the substrate according to Embodiment 5.

FIG. 29 A cross-sectional view taken along line A-A in FIG. 27.

FIG. 30 A cross-sectional view taken along line B-B in FIG. 27.

FIG. 31 A cross-sectional view taken along line C-C in FIG. 27.

FIG. 32 A cross-sectional view taken along line D-D in FIG. 27, in which a conductive member has a rectangular shape.

FIG. 33 A cross-sectional view taken along line D-D in FIG. 27, in which a conductive member has a triangular shape.

FIG. 34 A graph for demonstrating an improved effect of insertion loss characteristics according to Embodiment 5A and Embodiment 5B (which differ from each other in terms of a height of a conductive member) compared to a comparative example.

FIG. 35 A top view of a high-frequency transmission line and a substrate according to Embodiment 6 of this invention.

FIG. 36 A top view of the substrate according to Embodiment 6.

FIG. 37 A cross-sectional view taken along line A-A in FIG. 35.

FIG. 38 A cross-sectional view taken along line B-B in FIG. 35.

FIG. 39 A cross-sectional view taken along line C-C in FIG. 35.

FIG. 40 A cross-sectional view taken along line D-D in FIG. 35.

FIG. 41 A top view of the high-frequency transmission line and the substrate shown in FIG. 35, in which conductive members are formed on projecting portions of a coaxial connector.

FIG. 42 A cross-sectional view taken along line B-B in FIG. 41.

FIG. 43 A cross-sectional view taken along line D-D in FIG. 41.

FIG. 44 A graph for demonstrating an improved effect of insertion loss characteristics according to Embodiment 6A and Embodiment 6B (which differ from each other in terms of a projecting portion of an outer conductor and a height of a conductive member) compared to a comparative example.

FIG. 45 A top view of a high-frequency transmission line and a substrate according to Embodiment 7 of this invention.

FIG. 46 A top view of the substrate according to Embodiment 7.

FIG. 47 A cross-sectional view taken along line A-A in FIG. 45.

FIG. 48 A cross-sectional view taken along line B-B in FIG. 45.

FIG. 49 A cross-sectional view taken along line C-C in FIG. 45.

FIG. 50 A cross-sectional view taken along line D-D in FIG. 45.

FIG. 51 A cross-sectional view taken along line D-D in FIG. 45.

FIG. 52 A top view showing an example of a ground shown in FIG. 46.

FIG. 53 A top view showing a variation of a ground shown in FIG. 46.

FIG. 54 A top view showing a variation of a ground shown in FIG. 46.

FIG. 55 A graph for demonstrating an improved effect of insertion loss characteristics according to Embodiment 7A, Embodiment 7B and Embodiment 7C (which differ from each other in terms of a cutout shape of an exposed portion of a ground) compared to Embodiment 5B and a comparative example.

FIG. 56 A graph for demonstrating an improved effect of reflection characteristics according to Embodiment 7, Embodiment 7B and Embodiment 7C compared to Embodiment 5B.

FIG. 57 A top view of a high-frequency transmission line and a substrate according to Embodiment 8 of this invention.

FIG. 58 A top view of the substrate according to Embodiment 8.

FIG. 59 A cross-sectional view taken along line A-A in FIGS. 57 and 63.

FIG. 60 A cross-sectional view taken along line B-B in FIGS. 57 and 63.

FIG. 61 A cross-sectional view taken along line C-C in FIG. 57.

FIG. 62 A cross-sectional view taken along line D-D in FIG. 57.

FIG. 63 A top view of the high-frequency transmission line and the substrate according to Embodiment 8 of this invention, in which a projecting portion of a coaxial connector is electrically connected to an exposed portion of a ground via a conductive member.

FIG. 64 A cross-sectional view taken along line C-C in FIG. 63.

FIG. 65 A cross-sectional view taken along line D-D in FIG. 63.

FIG. 66 A top view showing an example of a ground shown in FIG. 58.

FIG. 67 A top view showing a variation of a ground shown in FIG. 58.

FIG. 68 A top view showing a variation of a ground shown in FIG. 58.

FIG. 69 A graph for demonstrating an improved effect of insertion loss characteristics according to Embodiment 8A, Embodiment 8B and Embodiment 8C compared to Embodiment 6B and a comparative example.

FIG. 70 A graph for demonstrating an improved effect of reflection characteristics according to Embodiment 8A, Embodiment 8B and Embodiment 8C compared to Embodiment 6B.

FIG. 71 A perspective view of a circuit module including a coaxial connector disclosed in Patent Document 1.

FIG. 72 A cross-sectional view taken along line B-B in FIG. 71.

FIG. 73 A perspective view of a high-frequency connector having a flange disclosed in Patent Document 2.

### MODE FOR CARRYING OUT THE INVENTION

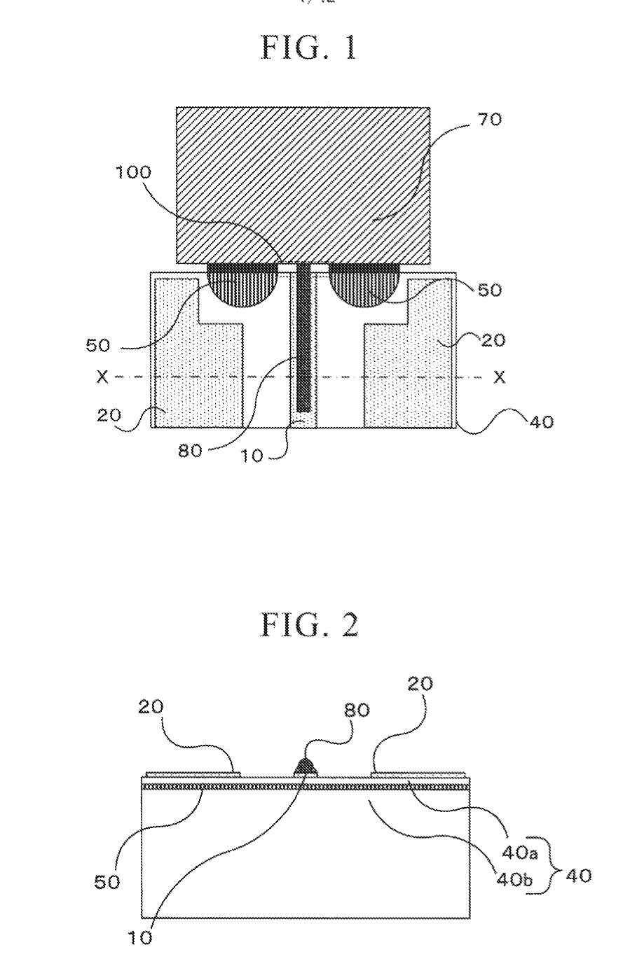

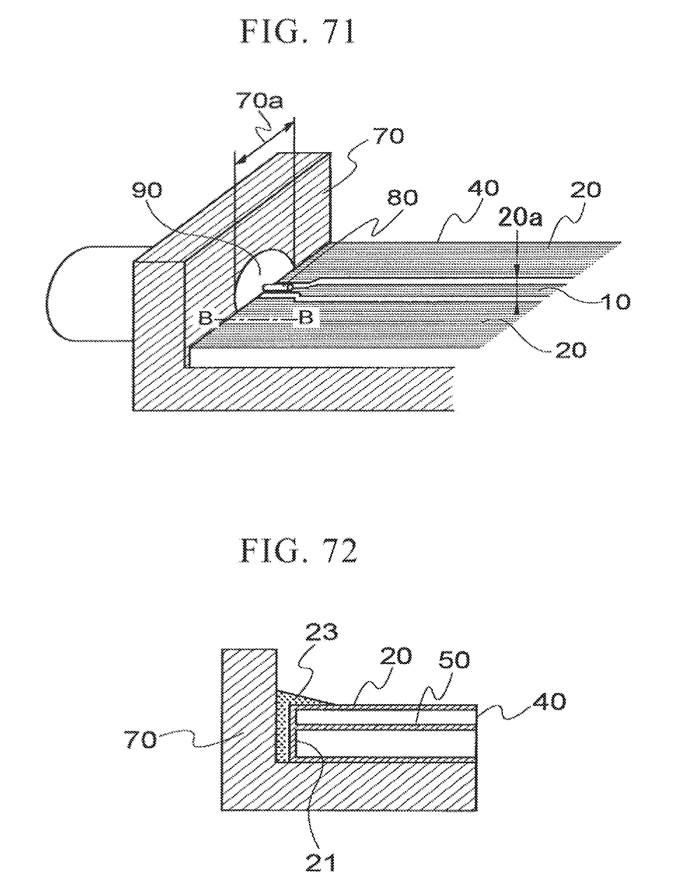

The basic principle of a circuit module and a substrate according to this invention will be described with reference to FIGS. 1 and 2. FIG. 1 is a top view of the circuit module, and FIG. 2 is a cross-sectional view taken along line X-X in FIG. 1. Herein, the constituent elements corresponding to the constituent elements shown in FIGS. 71 and 72 are designated by the same reference numerals.

A multilayered circuit substrate 40 shown in FIGS. 1 and 2 includes a first dielectric layer 40a, a signal line 10 connected to a core line 80 of a coaxial connector formed on the surface of the first dielectric layer 40a, first grounds which are formed on opposite sides of the signal line 10 with a clearance therebetween, a coplanar line having second grounds 50 formed on the backside of the first dielectric layer 40a, and a second dielectric layer 40b which is laminated with the first dielectric layer 40a so as to sandwich the second grounds 50 therebetween. The second grounds 50 are exposed from side areas of the signal line 10 at the terminal face coupled with the coaxial connector on either the surface of the first dielectric layer 40a or the other surface of the second dielectric layer 40b whose surface is disposed to face the first dielectric layer 40a, wherein the exposed portions thereof are connected to an outer conductor 70 of the coaxial connector.

As described above, the second grounds 50 constituting the coplanar line are exposed; this makes it easy to visually recognize the electrically connected state between the exposed portions and the outer conductor 70 of the coaxial connector; thus, it is possible to reliably connect them together. Even when a clearance gap 100 is formed between the second grounds 50 and the outer conductor 70 beneath the core line 80 of the coaxial connector, it is possible to easily limit the length of the clearance gap 100 in a direction perpendicular to a signal transmitting direction (i.e. a direction parallel to the line X-X); hence, it is possible to suppress electromagnetic emission, and it is possible to prevent an insertion loss from increasing due to electromagnetic emission.

### Embodiment 1

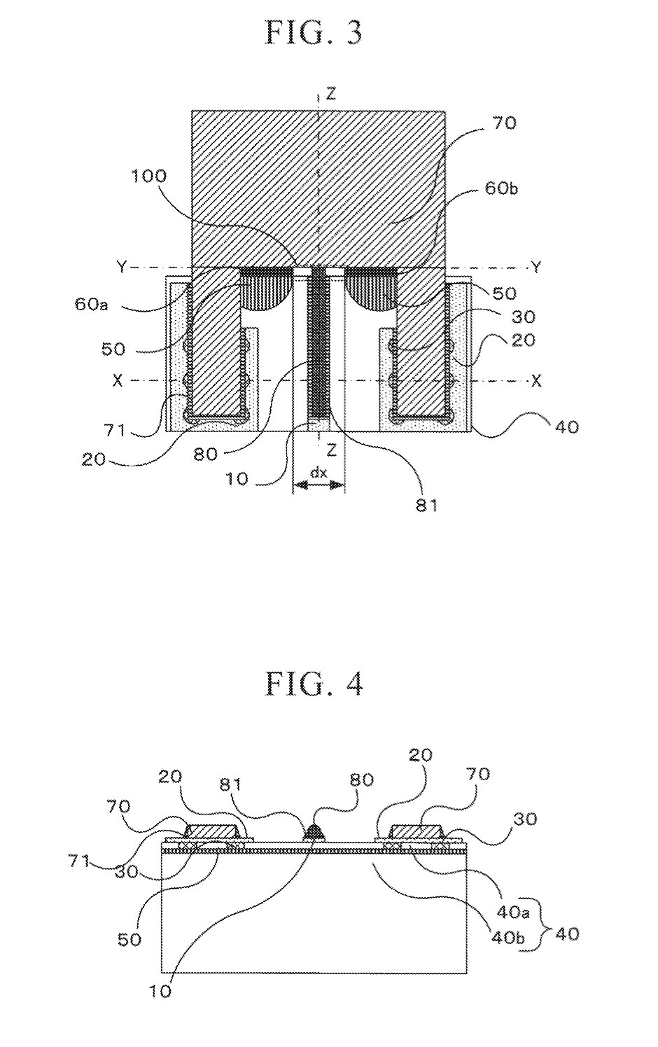

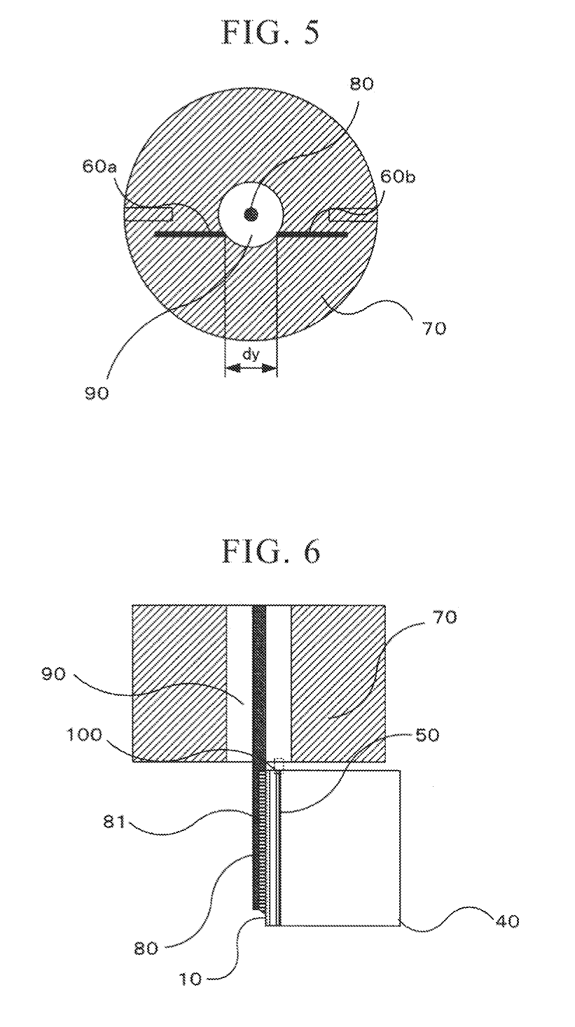

A high-frequency module according to Embodiment 1 of this invention will be described in detail with reference to FIGS. 3 to 8. FIG. 3 is a top view of the high-frequency module; FIG. 4 is a cross-sectional view taken along line X-X; FIG. 5 is a cross-sectional view taken alone line Y-Y in FIG. 3; and FIG. 6 is a cross-sectional view taken along line Z-Z in FIG. 3. Herein, the constituent elements corresponding to the constituent elements shown in FIGS. 71 and 72 are designated by the same reference numerals.

The high-frequency module according to Embodiment 1 includes a high-frequency substrate 40 composed of the dielectric layers 40a and 40b. The coplanar line is formed on the upper surface of the high-frequency substrate 40. The coplanar line includes the signal line 10 and the grounds 20 (or plane grounds) which are formed to sandwich the signal line 10 on the same layer as the signal line 10. As the lower grounds of the coplanar line, the plane-shaped grounds 50 are formed inside the high-frequency substrate 40. The grounds 20 of the coplanar line are mutually connected to the grounds 50, serving as the lower grounds of the coplanar line, via a plurality of conductive vias 30 which are disposed in a signal transmitting direction of the coplanar line with predetermined distances therebetween.

The coaxial connector of the high-frequency module according to Embodiment 1 includes the outer conductor 70, the core line 80 serving as the inner conductor, and the dielectric member 90. At the joint section between the coplanar line and the coaxial connector, the signal line 80 is electrically connected to the signal line via conductive members 81 composed of solders or conductive bonds. Similarly, the outer conductor 70 is electrically connected to the grounds 20 via conductive members 71 composed of solders or conductive bonds.

In this connection, the grounds are electrically connected to a pair of projecting portions, which project from the terminal face of the outer conductor 70 so as to place the core line 80 therebetween, via the conductive members 71.

The grounds 50 of the coplanar line (i.e. lower grounds) are exposed from the opposite areas, which place the signal line 10 therebetween, at the terminal face coupled with the coaxial connector on the surface of the high-frequency substrate 40. The exposed portions of the grounds 50 are securely connected to the outer conductor 70 of the coaxial connector via conductive members 60a and 60b composed of solders or conductive bonds.

It is preferable to set a minimum distance dx, lying between the grounds 50 exposed on the terminal face of the high-frequency substrate 40 coupled with the coaxial connector, to a desired value in response to the maximum frequency among signals transmitted in a desired frequency range. That is, it is preferable to limit the minimum distance dx, lying between the exposed portions of the grounds 50, to less than a half wavelength of the maximum frequency of transmitting signals in consideration of a shortening coefficient of wavelength. Thus, it is possible to suppress electromagnetic emission due to half-wavelength resonance occurring between the exposed portions of the grounds 50.

Specifically, it is preferable to satisfy Condition 1 (Equation 1), which limits the minimum distance dx [μm] to less than a half wavelength of the maximum frequency of transmitting signals in consideration of a shortening coefficient of wavelength in the dielectric layer 40b having a dielectric constant ∈b disposed just below the grounds 50, and Condition 2 (Equation 2) which limits the minimum distance dx [μm] to less than a half wavelength of the maximum frequency of transmitting signals in consideration of a shortening coefficient of wavelength in the dielectric layer 40a having a dielectric constant ∈a disposed just below the grounds 50. Herein, the speed of light is c=3.0×10⁸ [m/s]; the maximum frequency of transmitting signals is f [GHz]; the wavelength of the maximum frequency considering the shortening coefficient of wavelength of the dielectric layer 40b is λb [μm]; and the wavelength of the maximum frequency considering the shortening coefficient of wavelength of the dielectric layer 40a is λa [μm].

$$\begin{matrix}dx < \frac{λ b}{2} = \frac{c \times {10}^{- 3}}{2 \times f \times \sqrt{ɛ b}} & [ Equation 1 ] \\ dx < \frac{λ a}{2} = \frac{c \times {10}^{- 3}}{2 \times f \times \sqrt{ɛ a}} & [ Equation 2 ]\end{matrix}$$

When the grounds 50 are electrically connected to the outer conductor 70 of the coaxial connector via the conductive members 60a and 60b whilst dx, ∈a and ∈b are set to satisfy Equation 1 and Equation 2, it is possible to suppress frequency components of transmitting signals leaked from the clearance gap 100 to the dielectric layer 40b.

It is preferable that a minimum distance dy between the conductive members 60a and 60b along an intersection line, which is formed between an extension line of a direction for transmitting signals through the grounds 50 and the outer conductor 70 of the coaxial connector, be less than or equal to the foregoing minimum distance dx. Thus, it is possible to easily reproduce an interval between the conductive members 60a and 60b, which connect the grounds 50 and the outer conductor 70 together, based on the uniform distance dx.

As described above, the grounds 50 of the coplanar line are exposed from the opposite areas sandwiching the signal line 10 at the terminal face coupled with the coaxial connector on the surface of the high-frequency substrate 40, so that the outer conductor 70 of the coaxial connector is securely connected to the exposed portions of the grounds 50 via the conductive members 60a and 60b. For this reason, even when the clearance gap 100 is formed between the grounds 50 and the outer conductor 70 due to manufacturing error, it is possible to suppress frequency components of transmitting signals leaked from the clearance gap 100 by setting the minimum distance dx between the exposed portions of the grounds 50, the dielectric constant ∈a of the dielectric layer 40a and the dielectric constant ∈b of the dielectric layer 40b; thus, it is possible to reduce insertion loss due to electromagnetic emission.

The aforementioned effect is produced when the outer conductor 70 of the coaxial connector is electrically connected to the exposed portions of the grounds 50, wherein the exposed portions of the grounds 50 can be determined arbitrarily. Additionally, it is possible to determine whether or not to apply plating onto the terminal face of the high-frequency substrate 40 on which the grounds 50 are exposed. Furthermore, it is possible to determine whether or not to electrically connect the exposed portions of the grounds 50 to the plane-shaped grounds 20.

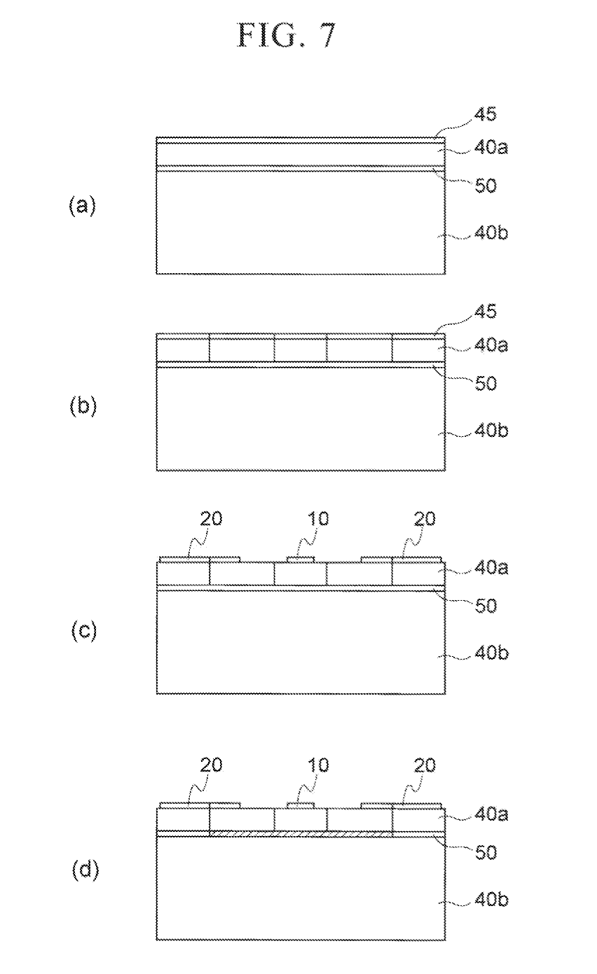

Next, a manufacturing method of the high-frequency substrate 40 will be described with reference to FIG. 7. Herein, FIGS. 7(a)-(d) are side views of the high-frequency substrate 40 connected with the coaxial connector.

FIG. 7(a): A conductive layer (or a second conductive layer) corresponding to the grounds 50, the dielectric layer 40a, and a dielectric layer 45 (or a first conductive layer) are sequentially formed on the dielectric layer 40b.

FIG. 7(b): A laser or drill is used to selectively remove the conductive layer 45 and the dielectric layer 40a, thus exposing the grounds on the opposite sides of the signal line 10 shown in FIG. 3.

FIG. 7(c): The conductive layer 45 is selectively removed so as to form the signal line 10 and the grounds 20 on the dielectric layer 40a.

FIG. 7(d): The high-frequency substrate 40 is thus produced and soldered with the coaxial connector. Soldering areas of the grounds 50 are denoted with slanted lines; but this is an exemplary illustration; hence, soldering can be applied to other areas other than the grounds 50. Additionally, soldering may not be always applied to these areas due to the clearance gap 100 (see FIG. 3) formed beneath the signal line 10.

In this connection, it is possible to implement a step of FIG. 7(b) for exposing the grounds 50 and a step of FIG. 7(c) for forming the surface pattern of the high-frequency substrate 40 in an arbitrary order.

Next, insertion loss characteristics of the high-frequency module according to Embodiment 1 will be described. The following numerical condition is adopted in order to verify insertion loss characteristics. The high-frequency substrate 40 is a multilayered wiring substrate composed of resins constituting the dielectric layer 40a having a dielectric constant 3.35, disposed above the grounds 50, and the dielectric layer 40b having a dielectric constant 4.85 disposed just below the grounds 50.

Additionally, the thickness of the dielectric layer 40a is 135 [μm]; the width of the signal line 10 is 30 [μm]; the interval between the signal line 10 and the ground 20 is 990 [μm]; the diameter of each conductive via 30 is 50 [μm]; and the interval between a plurality of conductive vias 30 in a direction of transmitting signals is 800 [μm]. The thickness of the signal line 10 and the thickness of the ground 20 are each 15 [μm]; and the thickness of the ground 50 is 35 [μm].

Furthermore, diameter of the dielectric member 90 having a dielectric constant 3.3 in the coaxial connector is 1397 [μm]; and the diameter of the core line 80 serving as the inner conductor is 300 [μm]. The exposed portion of the ground 50 has a semi-circular shape with a curvature radius of 400 [μm]; and the minimum distance dx between the exposed portions of the grounds 50 on the terminal face of the high-frequency substrate 40 is 1840 [μm]. Herein, a clearance gap is formed between the outer conductor 70 of the coaxial connector and the grounds 50; the interval between the outer conductor 70 and the grounds 50 is 100 [μm]; and the exposed portions of the grounds 50 are electrically connected to the outer conductor 70.

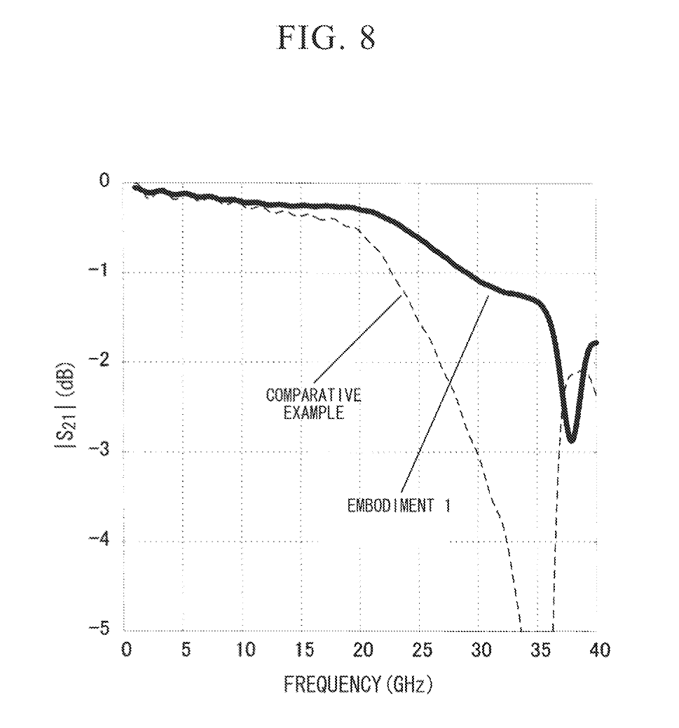

The foregoing numerical condition is used to analyze a comparative example, in which the grounds 50 have no exposed portions are not connected to the outer conductor 70 of the coaxial connector, and the high-frequency module of Embodiment 1 in which the minimum distance dx between the exposed portions of the grounds 50 on the terminal face of the high-frequency substrate 40 is set to 1840 [μm] and in which the exposed portions of the grounds 50 are electrically connected to the outer conductor 70 of the coaxial connector, thus making comparison therebetween with respect to an insertion loss characteristic (|S₂₁|). The analysis result is shown in FIG. 8.

FIG. 8 shows that the frequency range of the comparative example indicating an insertion loss of less than 2 dB is 0-27 GHz whilst the counterpart frequency range of Embodiment 1 of this invention is increased to 0-37 GHz; this demonstrates an improvement of about 10 GHz.

### Embodiment 2

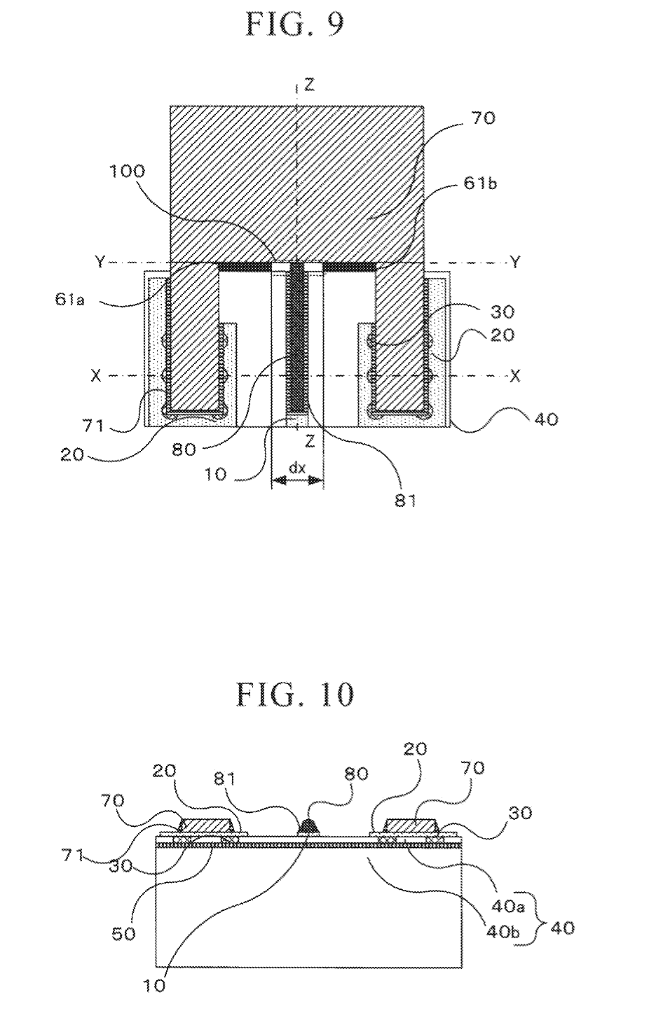

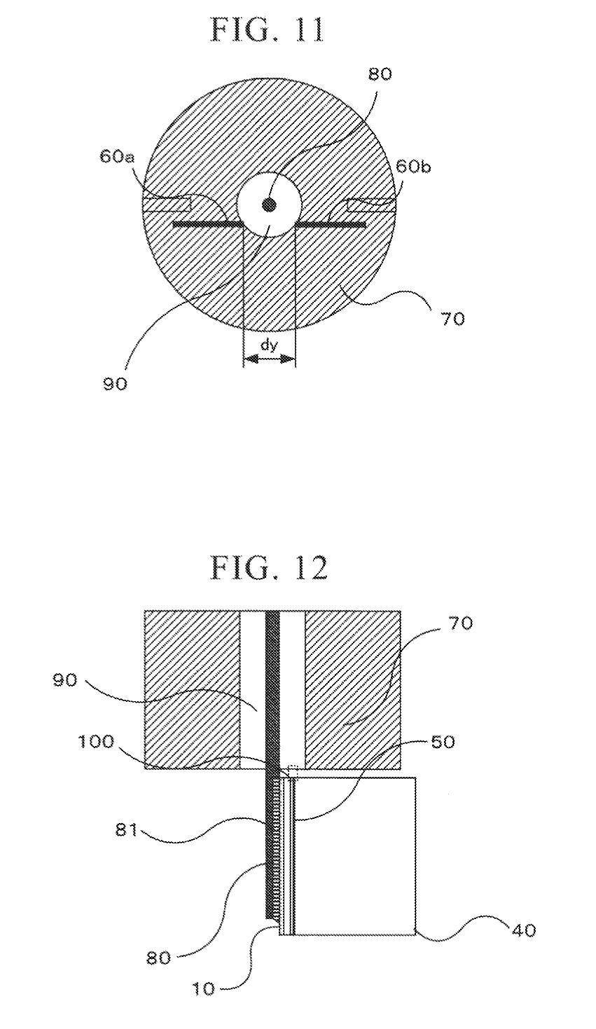

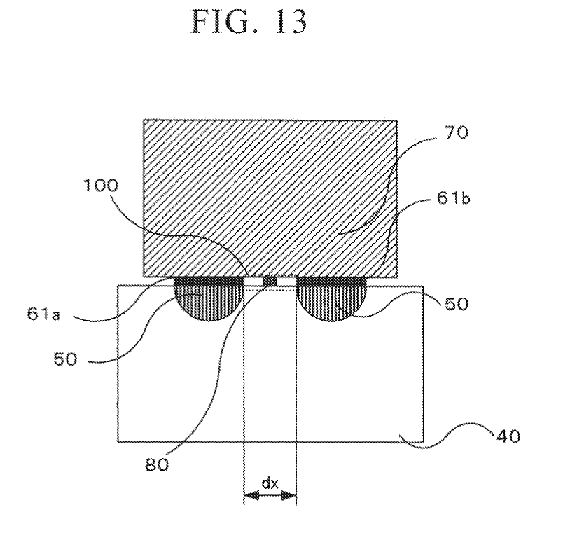

A high-frequency module and the high-frequency substrate 40 according to Embodiment 2 of this invention will be described with reference to FIGS. 9 to 15. FIG. 9 is a top view of the high-frequency module; FIG. 10 is a cross-sectional view taken along line X-X in FIG. 9; FIG. 11 is a cross-sectional view taken along line Y-Y in FIG. 9; FIG. 12 is a cross-sectional view taken along line Z-Z in FIG. 9; and FIG. 13 is a back view of the high-frequency module. Herein, the constituent elements corresponding to the constituent elements shown in FIGS. 71 and 72 are designated by the same reference numerals.

The coplanar line formed on the upper surface of the high-frequency substrate 40 of the high-frequency module according to Embodiment 2 includes the signal line 10 and the grounds 20 which are formed in the same layer as the signal line 10 so as to interpose the signal line 10 therebetween. As the lower ground of the coplanar line, the plane-shaped grounds 50 are formed inside the high-frequency substrate 40. The grounds 20 and 50 are mutually connected together via a plurality of conductive vias 30 which are aligned with predetermined intervals therebetween in the direction of transmitting signals through the coplanar line.

The coaxial connector of the high-frequency module according to Embodiment 2 includes the outer conductor 70, the core line 80 serving as the inner conductor, and the dielectric element 90. At the joint section between the coplanar line and the coaxial connector, the signal line 10 is electrically connected to the core line 80 via conductive members 81 composed of solders or conductive bonds. Similarly, the grounds 20 are electrically connected to the outer conductor 70 via conductive members 71 composed of solders or conductive bonds.

The foregoing configuration of Embodiment 2 is identical to that of Embodiment 1, whereas Embodiment 2 adopts the following modification to Embodiment 1. At the terminal face connected with the coaxial connector in either the surface or the backside of the high-frequency substrate 40 having the signal line 10, the grounds 50 of the coplanar line are exposed on the opposite areas besides the signal line 10. The exposed portions of the grounds 50 are securely connected to the outer conductor 70 via the conductive members 61a, 61b composed of solders or conductive bonds.

It is preferable that, in the terminal face of the high-frequency substrate 40 connected with the coaxial connector, the minimum distance dx between the exposed portions of the grounds 50 be set to a desired value in response to the maximum frequency of signals transmitted in a desired frequency range. That is, it is preferable that the minimum distance dx between the exposed portions of the grounds 50 be limited to less than a half wavelength of the maximum frequency of transmitting signals. Thus, it is possible to suppress electromagnetic emission due to half-wavelength resonance occurring between the exposed portions of the grounds 50.

Specifically, it is preferable to satisfy Equation 1, which limits the minimum distance dx to less than a half wavelength of the maximum frequency of transmitting signals in consideration of a shortening coefficient of wavelength in the dielectric layer 40b having the dielectric constant ∈b disposed just below the grounds 50, and Equation 2 which limits the minimum distance dx to less than a half wavelength of the maximum frequency of transmitting signals in consideration of a shortening coefficient of wavelength in the dielectric layer 40a having the dielectric constant ∈a disposed just above the grounds 50.

As described above, the grounds 50 are electrically connected to the outer conductor 70 via the conductive members 61a, 61b whilst dx, ∈a and ∈b are determined to satisfy Equation 1 and Equation 2, whereby it is possible to suppress frequency components of transmitting signals leaked into the dielectric layer 40b from the clearance gap 100 between the grounds 50 and the outer conductor 70.

Additionally, it is preferable that the minimum distance dy between the conductive members 61a and 61b be less than or equal to the minimum distance dx in the intersection line formed between the extension line of the direction of transmitting signals through the grounds 50 and the outer conductor 70 of the coaxial connector. Thus, it is possible to easily reproduce the distance dy between the conductive members 61a and 61b by which the grounds 50 are connected to the outer conductor 70.

As described above, in the high-frequency module according to Embodiment 2, the grounds 50 of the coplanar line are exposed in the opposite areas besides the signal line 10 in the terminal face connected with the coaxial connector in either the surface or the backside of the high-frequency substrate 40, wherein the exposed portions of the grounds 50 are securely connected to the outer conductor 70 of the coaxial connector via the conductive members 61a, 61b. For this reason, even when the clearance gap 100 is formed between the grounds 50 and the outer conductor 70 due to manufacturing error, it is possible to suppress frequency components of transmitting signals leaked into the clearance gap 100 and to thereby reduce an insertion loss due to electromagnetic emission since the minimum distance dx between the exposed portions of the grounds 50, and the dielectric constants ∈a, ∈b of the dielectric layers 40a, 40b are determined to satisfy Equation 1 and Equation 2.

The foregoing effect is secured as long as the outer conductor 70 of the coaxial connector is electrically connected to the exposed portions of the grounds 50, wherein the exposed portions of the grounds 50 can be formed in an arbitrary shape. Additionally, it is possible to determine whether or not to apply plating on the dielectric faces of the exposed portions of the grounds 50.

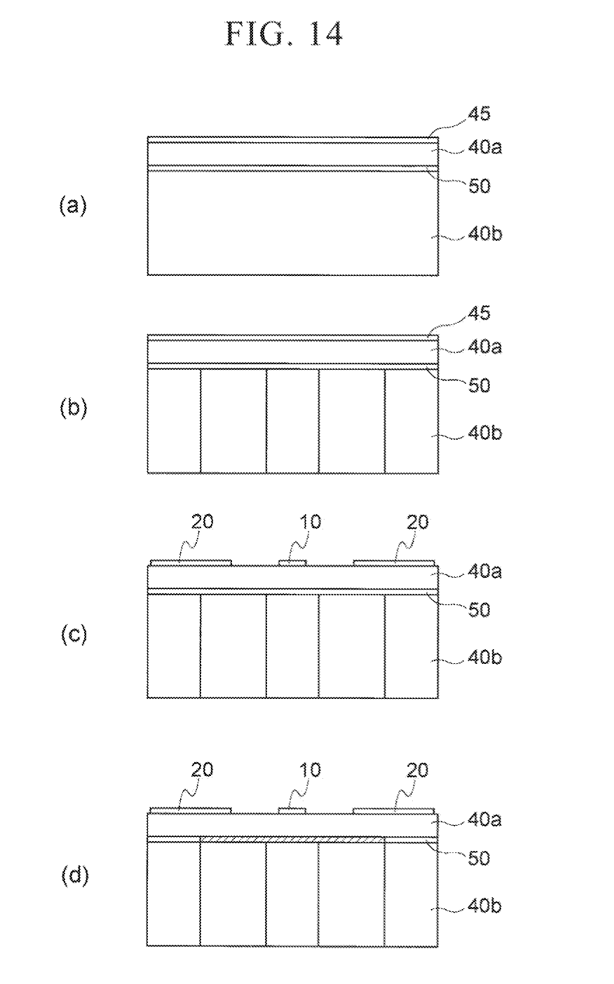

Next, a manufacturing method of the high-frequency substrate 40 according to Embodiment 2 will be described with reference to FIGS. 14(a)-(d). FIGS. 14(a)-(d) are side views of the high-frequency substrate 40 connected with the coaxial connector.

FIG. 14(a): The conductive layer 50 serving as the grounds 50, the dielectric layer 40a and the conductive layer 45 are sequentially formed on the dielectric layer 40b.

FIG. 14(b): A laser or drill is used to selectively remove the dielectric layer 40b so as to expose the grounds 50 on the opposite areas besides the signal line 10 as shown in FIG. 13.

FIG. 14(c): The conductive layer 45 is selectively removed so as to form the signal line 10 and the grounds 20 on the dielectric layer 40a. Certain portions of the grounds 50 are exposed in the opposite areas besides the signal line 10 in a perspective view through the signal line 10 (the conductive layer 45), the dielectric layer 40a and the grounds 50.

FIG. 14(d): Soldering areas for the grounds 50 are denoted using slanted lines. These soldering areas are illustrative; hence, soldering can be applied to other areas other than the grounds 50. Soldering is not necessarily applied to these areas due to the clearance gap 100 (see FIG. 9) formed beneath the signal line 10.

In this connection, it is possible to implement a step of FIG. 14(b) for exposing the grounds 50 and a step of FIG. 14(c) for forming the surface pattern in an arbitrary order.

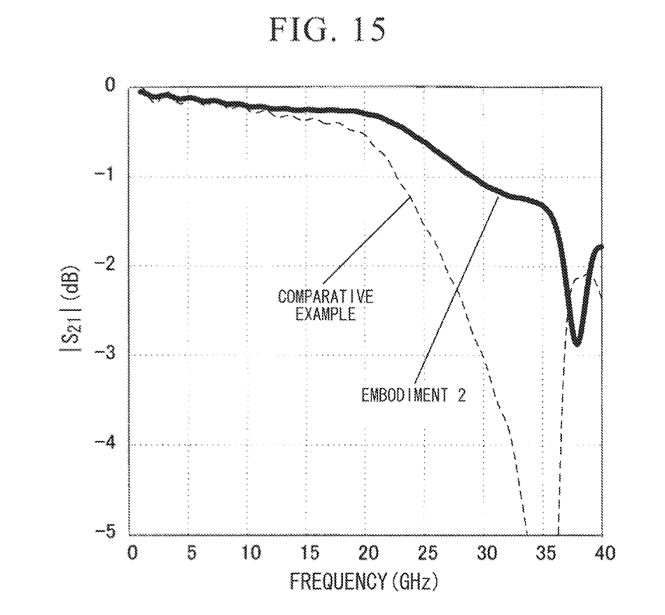

Next, insertion loss characteristics of the high-frequency module according to Embodiment 2 will be described with reference to FIG. 15. The following numerical condition is adopted in order to verify insertion loss characteristics. The high-frequency substrate 40 is a multilayered wiring substrate is composed of resins constituting the dielectric layer 40a having a dielectric constant 3.35 disposed above the grounds 50 and the dielectric layer 40b having a dielectric constant 4.85 disposed below the grounds 50.

The thickness of the dielectric layer 40a is 135 [μm]; the width of the signal line 10 is 300 [μm]; the interval between the signal line 10 and the grounds 20 is 990 [μm]; the diameter of the conductive via 30 is 50 [μm]; and the interval between a plurality of conductive vias 30 in the direction of transmitting signals is 800 [μm]. Additionally, the thickness of the signal line 10 and the thickness of the grounds 20 are each set to 15 [μm], and the thickness of the grounds 50 is set to 35 [μm].

In addition, the dielectric member 90 of the coaxial connector has a dielectric constant of 3.3; the diameter of the dielectric member 90 is 1397 [μm]; and the diameter of the core line 80 serving as the inner conductor is 300 [μm]. The exposed portions of the grounds 50 have a semi-circular shape with a curvature radius of 400 [μm], wherein the minimum distance dx between the exposed portions of the grounds 50 is 1840 [μm] on the terminal face of the high-frequency substrate 40. Furthermore, a clearance gap is formed between the outer conductor 70 of the coaxial connector and the grounds 50 such that the interval between the outer conductor 70 and the grounds 50 is 100 [μm], wherein the exposed portions of the grounds 50 are electrically connected to the outer conductor 70.

The foregoing numerical condition is used to analyze a comparative example, in which the grounds 50 having no exposed portions are not connected to the outer conductor 70, and Embodiment 2 in which the minimum distance dx between the exposed portions of the grounds 50 is 1840 [μm] on the terminal face of the high-frequency substrate 40 and in which the exposed portions of the grounds 50 are electrically connected to the outer conductor 70, thus making a comparison therebetween with respect to insertion loss (|S₂₁|) characteristics. The analysis result is shown in FIG. 15.

FIG. 15 shows that, compared to the comparative example, Embodiment 2 improves the frequency range whose insertion loss is less than 2 dB by about 10 GHz, from 0-27 GHz to 0-37 GHz.

### Embodiment 3

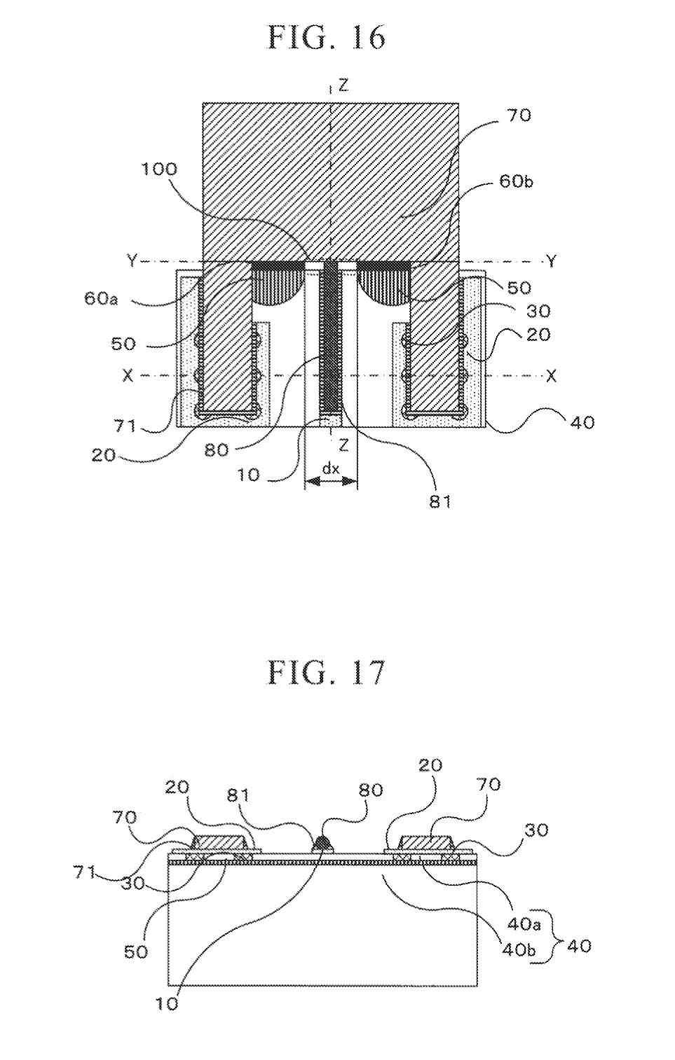

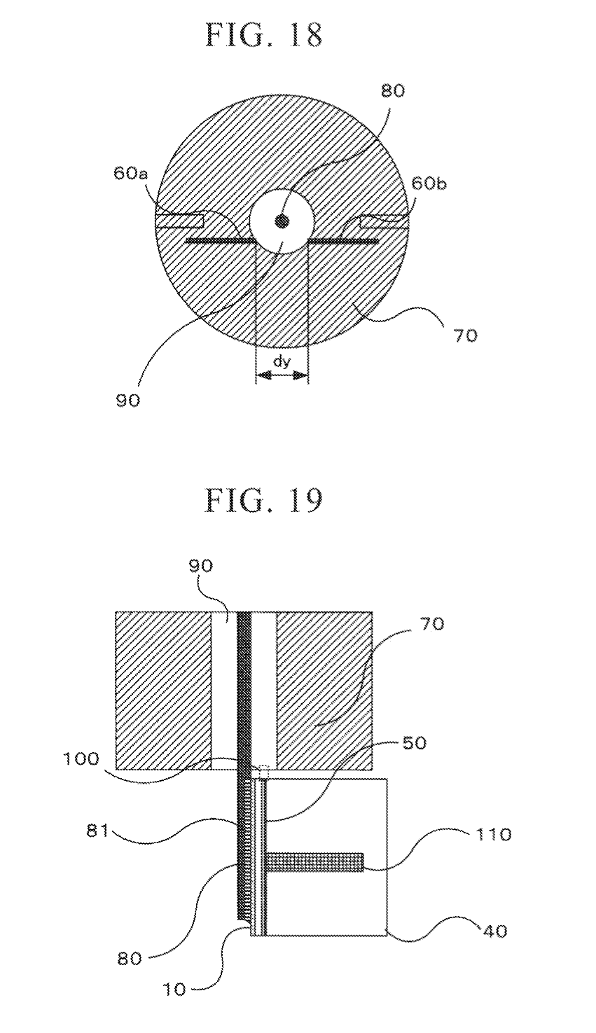

Next, the high-frequency module and the high-frequency substrate 40 according to Embodiment 3 of this invention will be described with reference to FIGS. 16-20. FIG. 16 is a top view of the high-frequency module and the high-frequency substrate 40 according to Embodiment 3; FIG. 17 is a cross-sectional view taken along line X-X in FIG. 16; FIG. 18 is a cross-sectional view taken along line Y-Y in FIG. 16; and FIG. 19 is a cross-sectional view taken along line Z-Z in FIG. 16. Herein, the constituent elements corresponding to the constituent elements shown in FIGS. 71 and 72 are designated by the same reference numerals.

Embodiment 3 applies the following modification to Embodiment 1. As shown in FIG. 19, a conductive via 110 is formed beneath the ground 50. That is, it is preferable that at least one conductive via 110 be formed on the intersection line depicted between the ground 50 and the vertical line (the cross-sectional line Z-Z) including the symmetrical line of the signal line 10. Thus, a part of transmitting signals leaked from the clearance gap between the outer conductor 70 and the grounds 50 propagates through the dielectric substance below the grounds 50, whereby it is possible to maximally intensify the electric field distribution in proximity to the intersection line depicted between the ground 50 and the vertical line (the cross-sectional line Z-Z) including the symmetrical line of the signal line 10. FIG. 19 shows a single conductive via 110, but it is possible to form a plurality of conductive vias 110.

A manufacturing method of the high-frequency substrate 40 according to Embodiment 3 further includes a step for forming the conductive via 110 directing from the ground 50 to the dielectric layer 40b in addition to the foregoing steps of FIGS. 7(a)-(c).

Next, insertion loss characteristics of the high-frequency module according to Embodiment 3 will be described. The same numerical condition as Embodiment 1 is adopted in order to verify insertion loss characteristics, wherein the conductive via 110 is aligned along the center position, which departs from the terminal face of the high-frequency substrate 40 connected with the coaxial connector by 920 [μm], and wherein the length thereof is 1070 [μm], and the diameter thereof is 300 [μm].

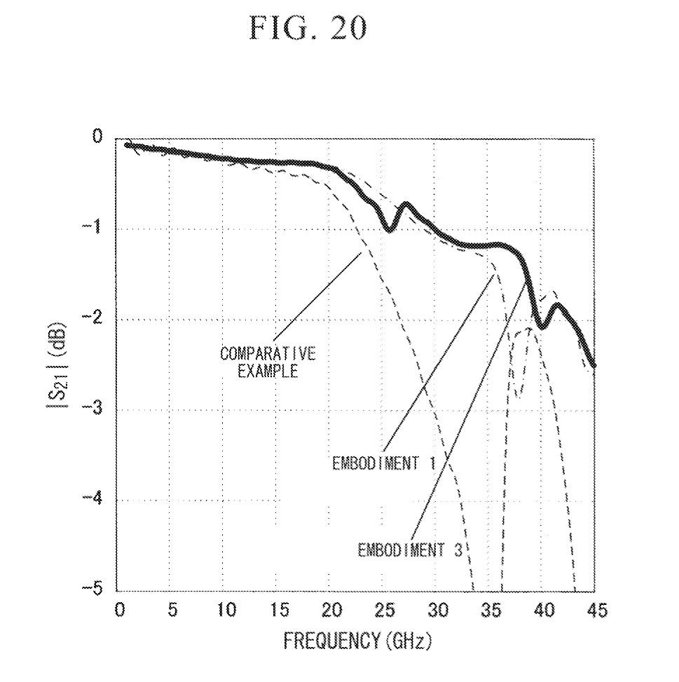

The foregoing numerical condition is used to analyze a comparative example, in which the grounds 50 having no exposed portions are not connected to the outer conductor 70 of the coaxial connector and in which the conductive via 110 is not formed, Embodiment 1 in which the minimum distance dx between the exposed portions of the grounds 50 is set to 1840 [μm] on the terminal face of the high-frequency substrate 40, the exposed portions of the grounds 50 are electrically connected to the outer conductor 70 of the coaxial connector, but the conductive via 110 is not formed, and Embodiment 3 in which the minimum distance dx between the exposed portions of the grounds 50 is set to 1840 [μm] on the terminal face of the high-frequency substrate 40, the exposed portions of the grounds 50 are electrically connected to the outer conductor 70 of the coaxial connector, and the conductive via 110 is formed, thus making comparison therebetween with respect to insertion loss (|S₂₁|) characteristics. The analysis result is shown in FIG. 20.

As shown in FIG. 20, the comparative example indicates 0-27 GHz as the frequency range whose insertion loss is less than 2 dB, whilst Embodiment 3 indicates 0-40 GHz, demonstrating an improvement of about 13 GHz. Additionally, Embodiment 3 compared to Embodiment 1 is able to shift a dip, appearing close to the frequency of 37 GHz, in a higher frequency side, wherein the depth of a dip is reduced by about 0.8 dB.

### Embodiment 4

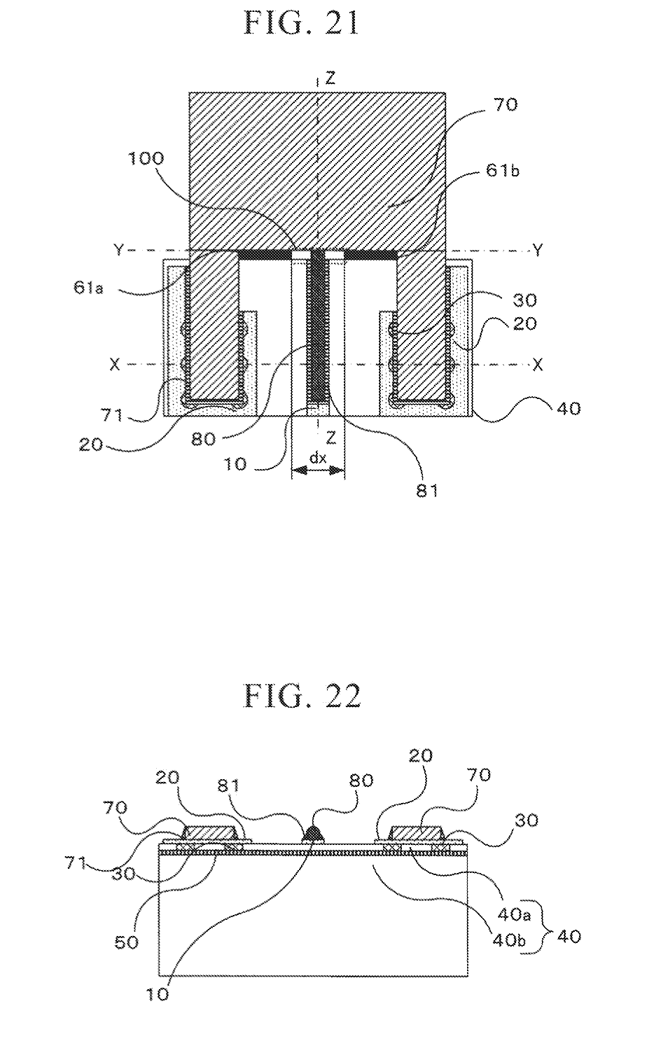

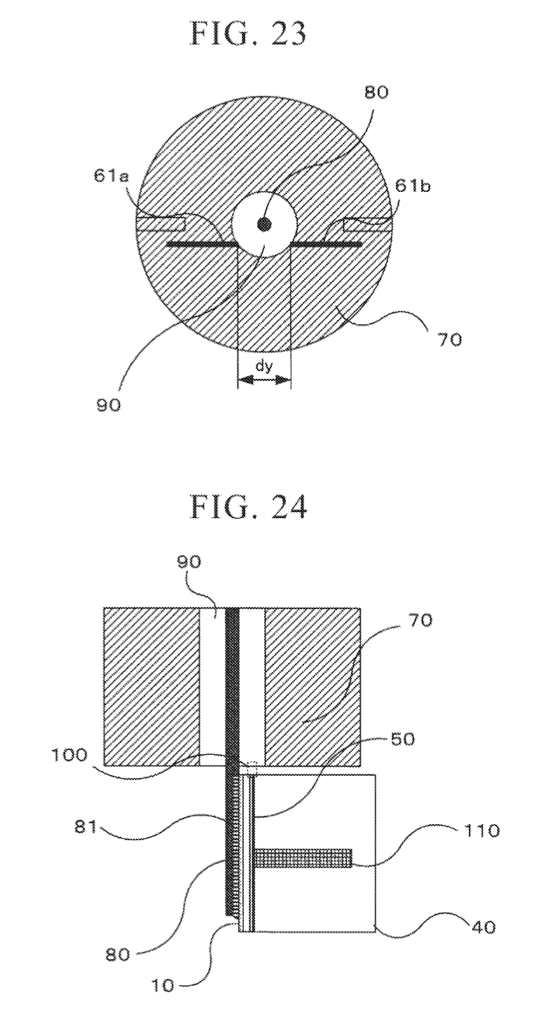

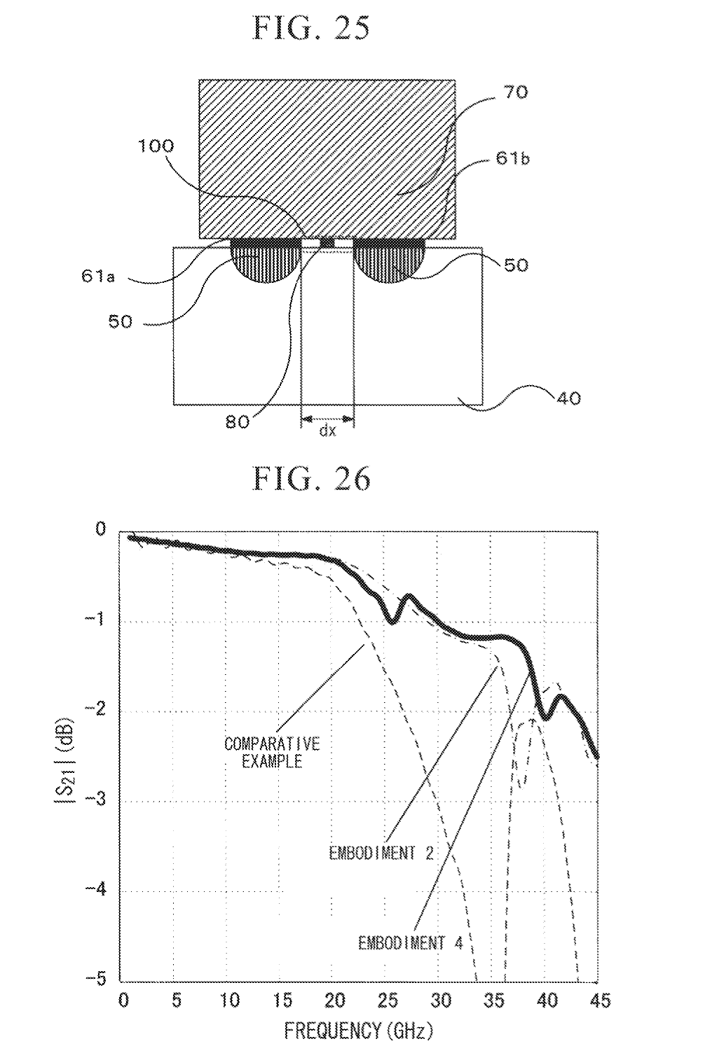

Next, a high-frequency module and the high-frequency substrate 40 according to Embodiment 4 of this invention will be described with reference to FIGS. 21-26. FIG. 21 is a top view of the high-frequency module and the high-frequency substrate 40 according to Embodiment 4; FIG. 22 is a cross-sectional view taken along line X-X in FIG. 21; FIG. 23 is a cross-sectional view taken along line Y-Y in FIG. 21; and FIG. 24 is a cross-sectional view taken along line Z-Z in FIG. 21. FIG. 25 is a back view of the high-frequency module and the high-frequency substrate 40 according to Embodiment 4. Herein, the constituent elements corresponding to the constituent elements shown in FIGS. 71 and 72 are designated by the same reference numerals.

Embodiment 4 applies the following modification to Embodiment 2. As shown in FIG. 24, the conductive via 110 is formed beneath the grounds 50. That is, it is preferable that at least one conductive via 110 be formed on the intersection line depicted between the ground 50 and the vertical line (Z-Z cross section) including the symmetrical line of the signal line 10. Thus, a part of transmitting signals leaked from the clearance gap between the grounds 50 and the outer conductor 70 propagates through the dielectric substance beneath the grounds 50, thus maximally intensifying the electric field distribution in proximity to the intersection line depicted between the ground 50 and the vertical line (Z-Z cross section) including the symmetrical line of the signal line 10. FIG. 24 shows a single conductive via 110, but it is possible to form a plurality of conductive vias 110.

A manufacturing method of the high-frequency substrate 40 according to Embodiment 4 further includes a step for forming the conductive via 110 directing from the ground 50 to the dielectric layer 40b in addition to the foregoing steps of FIGS. 14(a)-(c).

Next, insertion loss characteristics of the high-frequency module according to Embodiment 4 will be described. The same numerical condition as Embodiment 2 is adopted in order to verify insertion loss characteristics, wherein the conductive via 110 is aligned at the center position which departs from the terminal face of the high-frequency substrate 40 connected with the coaxial connector by 920 [μm], and wherein the length thereof is set to 1070 [μm], and the diameter thereof is set to 300 [μm].

The foregoing numerical condition is used to analyze a comparative example in which the grounds 50 having no exposed portions are not connected to the outer conductor 70 and the conductive via 110 is not formed, Embodiment 2 in which the minimum distance dx between the exposed portions of the grounds 50 on the terminal face of the high-frequency substrate 40 is set to 1840 [μm], the exposed portions of the grounds 50 are electrically connected to the outer conductor 70 of the coaxial connector but the conductive via 110 is not formed, and Embodiment 4 in which the minimum distance dx between the exposed portions of the grounds 50 on the terminal face of the high-frequency substrate 40 is set to 1840 [μm], the exposed portions of the grounds 50 are electrically connected to the outer conductor 70 of the coaxial connector, and the conductive via 110 is formed, thus making comparison therebetween with respect to insertion loss (|S₂₁|) characteristics. The analysis result is shown in FIG. 26.

FIG. 26 shows that the comparative example indicates 0-27 GHz as the frequency band whose insertion loss is less than 2 dB whilst Embodiment 4 indicates 0-40 GHz, demonstrating an improvement of about 13 GHz. Compared to Embodiment 2, Embodiment 4 is able to shift a dip, appearing close to the frequency of 37 GHz, in a higher frequency side, wherein the depth of a dip is reduced by about 0.8 dB.

Embodiments 1-4 employ conductive vias as a means to connect different layers; but this is not a restriction. For instance, it is possible to employ other electrical connecting means including through-holes having conductivity. The applied field of Embodiments 1-4 is not necessarily limited to high-frequency substrates; hence, these embodiments can be applied to various types of substrates of circuit modules. Furthermore, Embodiments 1-4 can be applied to substrates of circuit modules incorporated into electronic devices and information communication terminals such as portable telephones and PDAs (Personal Digital Assistants).

### Embodiment 5

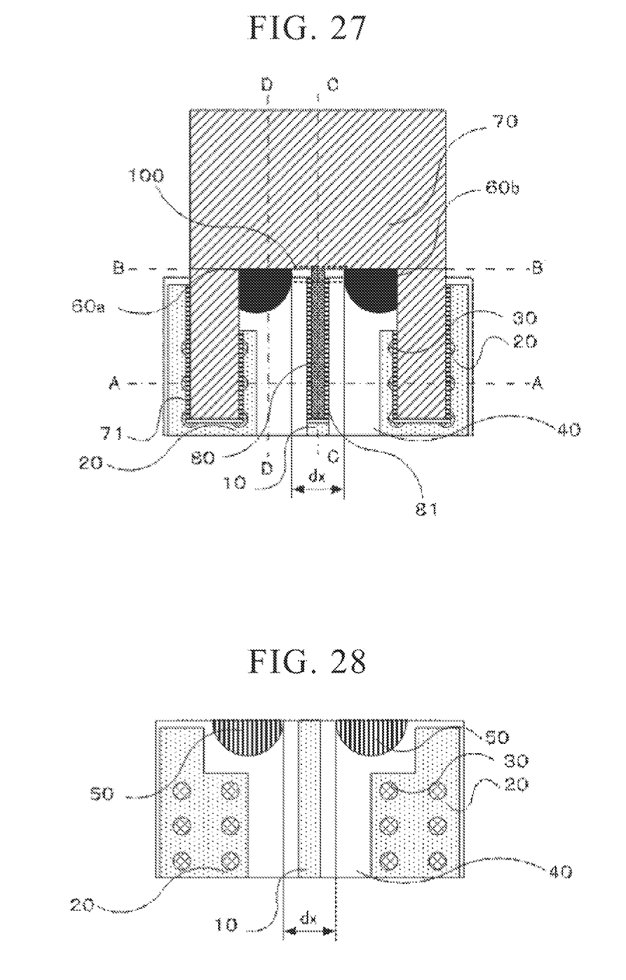

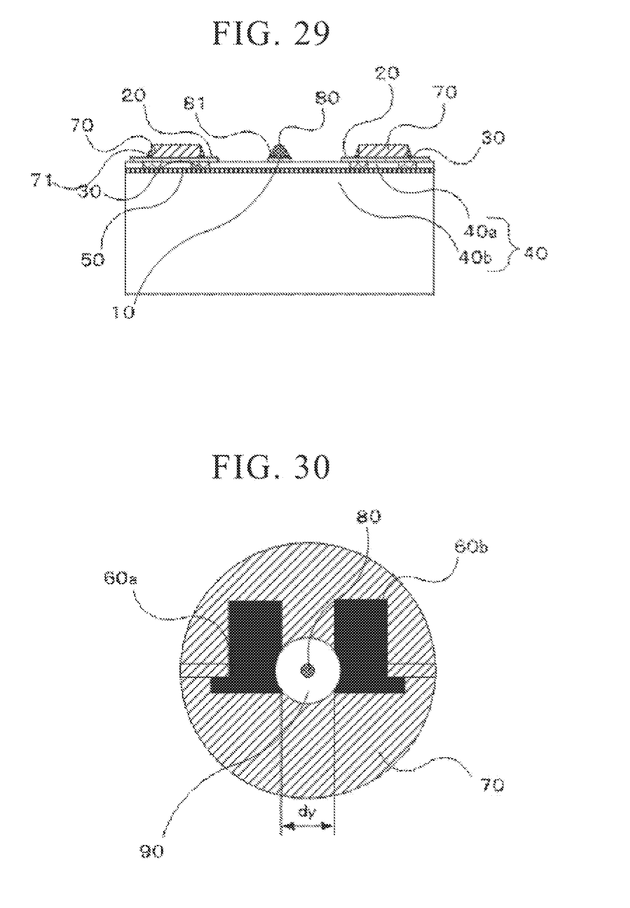

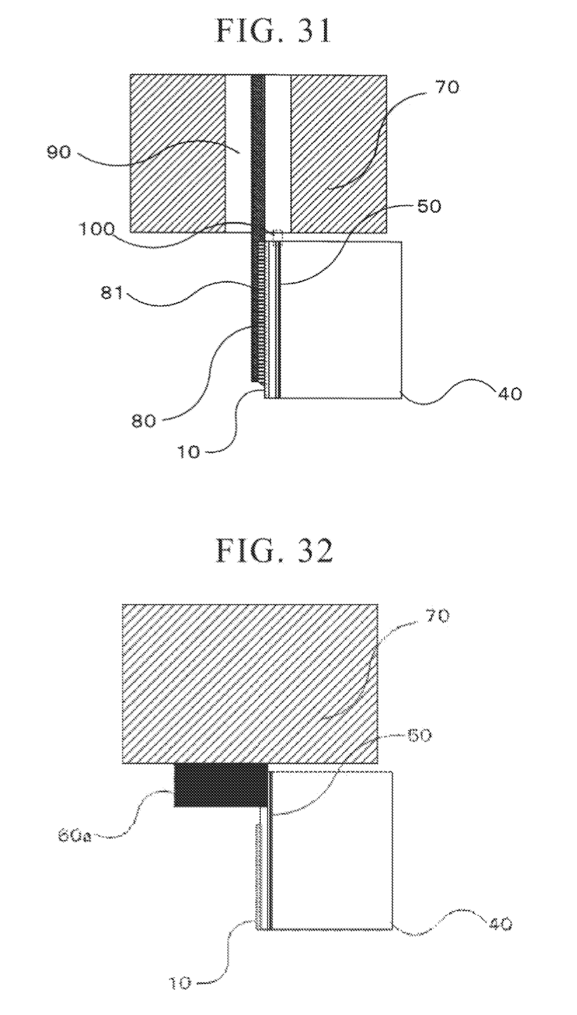

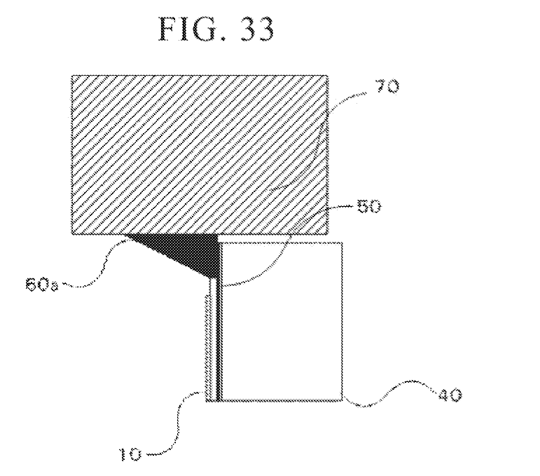

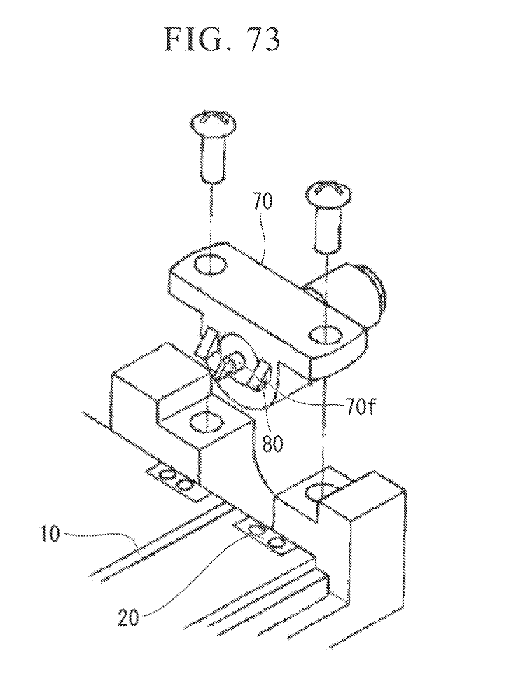

Next, a high-frequency transmission line and the high-frequency substrate 40 according to Embodiment 5 of this invention will be described with reference to FIGS. 27-34. FIG. 27 is a top view of the high-frequency transmission line and the high-frequency substrate 40 according to Embodiment 5; FIG. 28 is a top view showing the high-frequency substrate 40 alone; FIG. 29 is a cross-sectional view taken along line A-A in FIG. 27; FIG. 30 is a cross-sectional view taken along line B-B in FIG. 27; FIG. 31 is a cross-sectional view taken along line C-C in FIG. 27; and FIGS. 32-33 are cross-sectional views taken along line D-D in FIG. 27. Herein, the constituent elements corresponding to the constituent elements shown in FIGS. 71, 72 and 73 are designated by the same reference numerals.

The coplanar line formed on the upper surface of the high-frequency substrate 40 according to Embodiment 5 is configured of the signal line 10 and the grounds 20 which are formed in the same layer as the signal line 10 so as to interpose the signal line 10 therebetween. As the lower ground of the coplanar line, the plane-shaped grounds 50 are formed inside the high-frequency substrate 40. The grounds 20 and 50 are mutually connected together via a plurality of conductive vias 30 which are aligned with predetermined intervals therebetween in the direction of transmitting signals through the coplanar line. The coaxial connector is configured of the outer conductor 70, the core line 80 serving as the inner conductor, and the dielectric member 90. At the joint section between the coplanar line and the coaxial connector, the signal line 10 is electrically connected to the core line 80 via conductive members 81 composed of solders or conductive bonds. Similarly, the grounds 20 are electrically connected to the outer conductor 70 via conductive members 71 composed of solders or conductive bonds.

The grounds 50 of the coplanar line are exposed in the opposite areas beside the signal line 10 on the terminal face of the high-frequency substrate 40 connected with the coaxial connector, wherein the exposed portions thereof are securely connected to the outer conductor 70 via the conductive members 60a, 60b composed of solders or conductive bonds.

It is preferable that a connected area established between the grounds 50 and the outer conductor 70 via the conductive members 60a, 60b be formed upwardly to continue from the extension line of the coplanar line depicted in the direction of transmitting signals through the lower grounds 50 and be higher than the center position of the core line 80 of the coaxial connector. It is preferable that the exposed portions of the grounds 50 be entirely connected with the conductive members 60a, 60b on the terminal face of the high-frequency substrate 40. Since the ground structure gradually varies in the direction from the lower grounds 50 of the coplanar line to the outer conductor 70 of the coaxial connector, it is possible to alleviate significant variations of the electric field distribution, which may undergo when signals are transmitted from the coplanar line to the coaxial connector or from the coaxial connector to the coplanar line, at the joint section between the coaxial connector and the coplanar line. The cross-sectional shapes of the conductive members 60a, 60b observed in the direction of transmitting signals can be determined arbitrarily. For instance, the conductive members 60a, 60b can be formed in rectangular shapes (prism shapes as three-dimensional structures) as shown in FIG. 32; alternatively, the conductive members 60a, 60b can be formed in triangular shapes (wedge shapes as three-dimensional structures) as shown in FIG. 33.

It is preferable that the minimum distance dx between the exposed portions of the grounds 50 on the terminal face of the high-frequency substrate 40 be set to a desired value in response to the maximum frequency of signals transmitted in a desired frequency range. That is, it is preferable that the minimum distance dx between the exposed portions of the grounds 50 be limited to less than a half wavelength of the maximum frequency of transmitting signals. Thus, it is possible to suppress electromagnetic emission due to half-wavelength resonance occurring between the exposed portions of the grounds 50 in consideration of a shortening coefficient of wavelength.

Specifically, it is preferable to satisfy Condition 1 (Equation 1) which limits the minimum distance dx to a half wavelength of the maximum frequency of transmitting signals or less in consideration of a shortening coefficient of wavelength owing to the dielectric layer 40b of the dielectric constant ∈b disposed just below the grounds 50, and Condition 2 (Equation 2) which limits the minimum distance dx to a half wavelength of the maximum frequency of transmitting signals or less in consideration of a shortening coefficient of wavelength owing to the dielectric layer 40a of the dielectric constant ∈a disposed just above the grounds 50. Herein, the speed of light is c=3.0×10⁸ [m/s]; the maximum frequency of transmitting signals is f [GHz]; the wavelength of the maximum frequency considering the shortening coefficient of wavelength owing to the dielectric layer 40b is λb [μm]; and the wavelength of the maximum frequency considering the shortening coefficient of wavelength owing to the dielectric layer 40a is λa [μm].

When the grounds 50 are electrically connected to the outer conductive 70 via the conductive members 60a, 60b whilst dx, ∈a, ∈b are determined to satisfy Equation 1 and Equation 2, it is possible to suppress frequency components of transmitting signals leaked into the dielectric layer 40b from the clearance gap 100 between the grounds 50 and the outer conductor 70. Additionally, it is preferable that the minimum distance dy between the conductive members 60a and 60b be less than or equal to the minimum distance dx between the exposed portions of the grounds 50 on the intersection line depicted between the outer conductor 70 of the coaxial connector and the extension line of the ground 50 in the direction of transmitting signals. Thus, it is possible to easily reproduce the interval between the conductive members 60a and 60b connecting the grounds 50 and the outer conductor 70.

In the high-frequency transmission line according to Embodiment 5, the grounds 50 of the coplanar line are exposed in the opposite areas beside the signal line 10 on the terminal face of the high-frequency substrate 40; hence, it is possible to securely connect the exposed portions to the outer conductor 70 of the coaxial connector via the conductive members 60a, 60b. For this reason, even when the clearance gap 100 is formed between the grounds 50 and the outer conductor 70 due to manufacturing error, it is possible to suppress frequency components of transmitting signals leaked from the clearance gap 100 and to thereby reduce an insertion loss due to electromagnetic emission since the minimum distance dx between the exposed portions of the grounds 50 on the terminal face of the high-frequency substrate 40, the dielectric constant ∈a of the dielectric layer 40a, and the dielectric constant ∈b of the dielectric layer 40b are determined to satisfy Equation 1 and Equation 2.

The foregoing effect is secured as long as the exposed portions of the grounds 50 are electrically connected to the outer conductor 70 of the coaxial connector; hence, the exposed portions of the grounds 50 can be formed in an arbitrary shape. Additionally, it is possible to determine whether or not to apply plating on the dielectric faces of the exposed portions of the grounds 50. Furthermore, it is possible to determine whether or not to establish electrical connection on the dielectric faces between the exposed portions of the grounds 50 and the plane-shaped grounds 20.

Next, insertion loss characteristics of the high-frequency transmission line according to Embodiment 5 will be described. The following numerical condition is adopted to verify insertion loss characteristics. The high-frequency substrate 40 is a multilayered wiring substrate composed of resins constituting the dielectric layer 40a of the dielectric constant 3.88 disposed above the grounds 50 and the dielectric layer 40b of the dielectric constant 4.85 disposed just below the grounds 50. Herein, the thickness of the dielectric layer 40a is 250 [μm]; the width of the signal line 10 is 450 [μm]; the interval between the signal line 10 and the grounds 20 is 880 [μm]; the diameter of the conductive via 30 is 250 [μm]; and the interval between a plurality of conductive vias 30 in the direction of transmitting signals is 500 [μm]. Additionally, the thickness of the signal line 10 and the thickness of the ground 20 are each set to 71 [μm], and the thickness of the ground 50 is set to 35 [μm]. The dielectric member 90 of the coaxial connector has a dielectric constant of 3.3 and the diameter thereof is 1397 [μm], whilst the diameter of the core line 80 of the inner conductor is 300 [μm]. The exposed portion of the ground 50 has a semi-circular shape with a curvature radius of 400 [μm], wherein the minimum distance dx between the peripheries of the exposed portions is 1000 [μm]. Furthermore, a clearance gap is formed between the grounds 50 and the outer conductor 70 such that the distance thereof is 100 [μm], wherein the exposed portions of the grounds 50 are electrically connected to the outer conductor 70.

The foregoing numerical condition is used to analyze a comparative example in which the grounds 50 having no exposed portions are not connected to the outer conductor 70 of the coaxial connector, and Embodiment 5 in which the minimum distance dx between the exposed portions of the grounds 50 on the terminal face of the high-frequency substrate 40 is 1000 [μm] and in which the exposed portions of the grounds 50 are electrically connected to the outer conductor 70 of the coaxial connector, thus making comparison therebetween with respect to insertion loss (|S₂₁|) characteristics. The analysis result is shown in FIG. 34. As shown in FIGS. 27, 30 and 32, Embodiment 5 is designed such that the exposed portions of the grounds 50 are electrically connected to the outer conductor 70 of the coaxial connector via the conductive members 60a, 60b each having a semi-circular shape. FIG. 34 shows two characteristic curve with respect to Embodiment 5A in which the height of the conductive members 60a, 60b measured upwardly from the lower ground is set to 321 [μm], and Embodiment 5B in which the height is set to 1199 [μm].

FIG. 34 shows that the comparative example indicates 0 to 16.5 GHz as the frequency range whose insertion loss is less than 1 dB, whilst Embodiment 5A indicates 0-47 GHz demonstrating an improvement of about 30 GHz, and Embodiment 5B indicates 0-60 GHz demonstrating an improvement of about 44 GHz.

### Embodiment 6

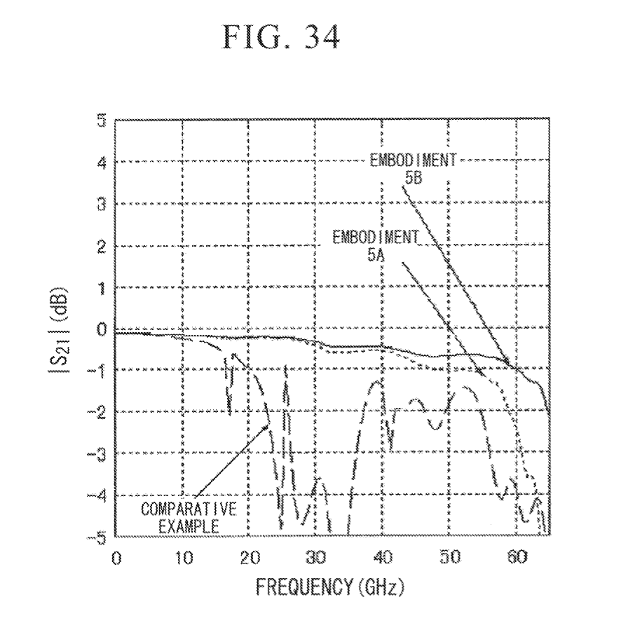

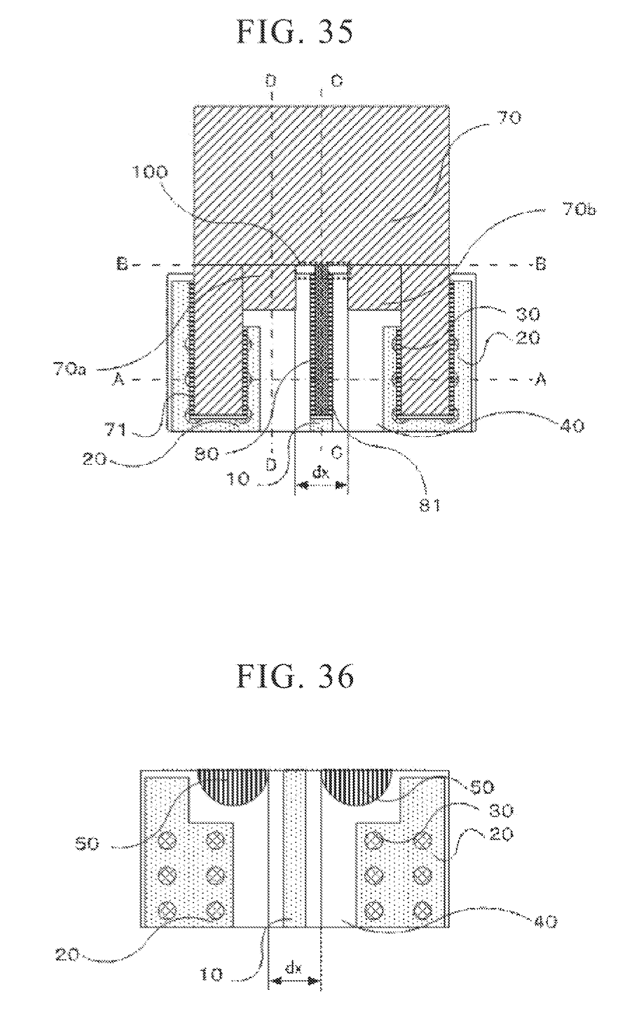

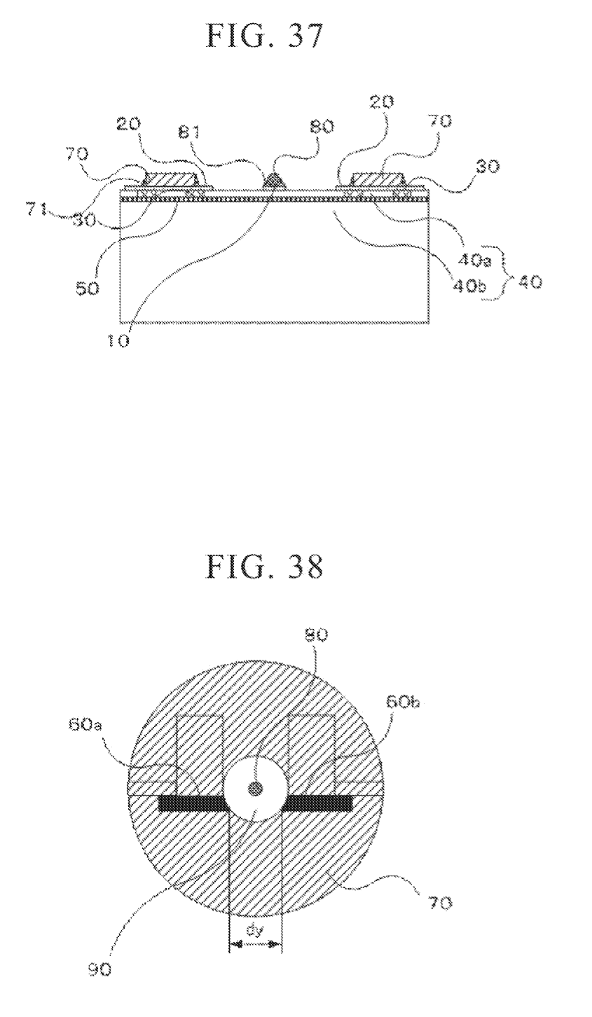

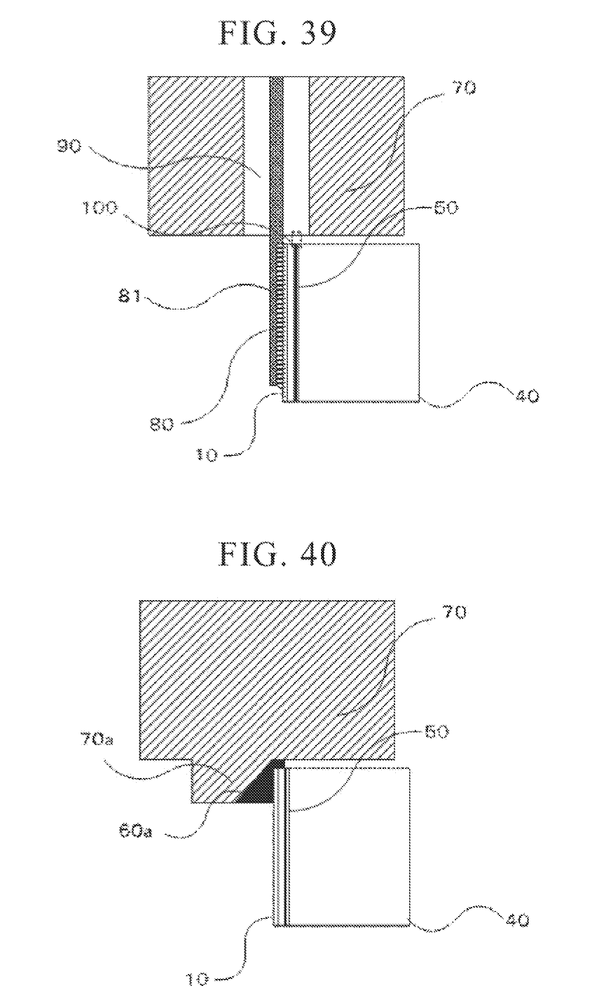

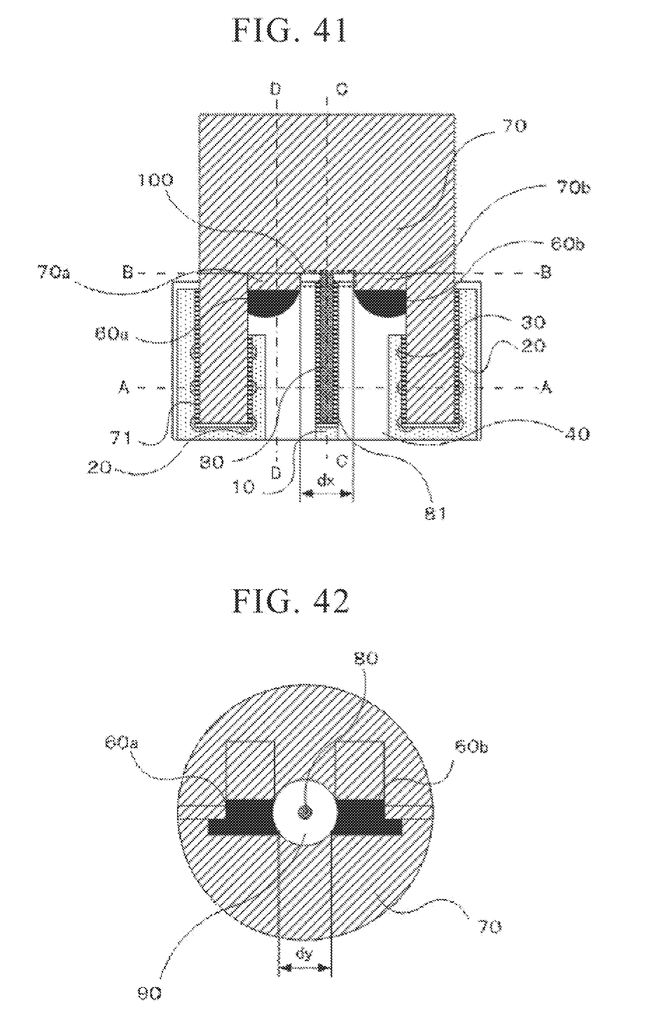

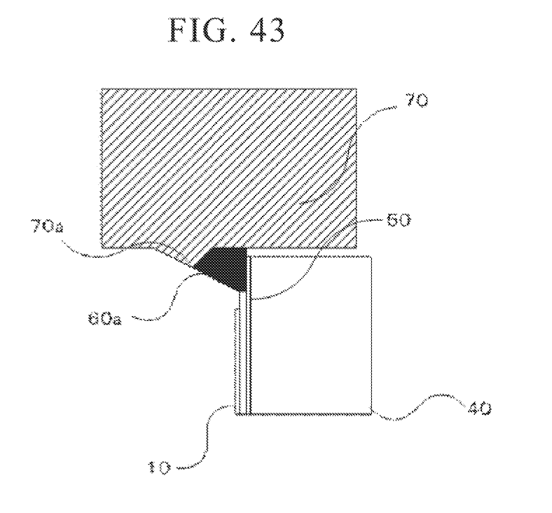

Next, a high-frequency transmission line and the high-frequency substrate 40 according to Embodiment 6 of this invention will be described with reference to FIGS. 35-44. FIGS. 35 and 41 are top views showing the high-frequency transmission line and the high-frequency substrate 40 according to Embodiment 6; FIG. 36 is a top view showing the high-frequency substrate 40 alone; FIG. 37 is a cross-sectional view taken along line A-A in FIGS. 35 and 41; FIG. 38 is a cross-sectional view taken along line B-B in FIG. 35; FIG. 39 is a cross-sectional view taken along line C-C in FIGS. 35 and 41; and FIG. 40 is a cross-sectional view taken along line D-D in FIG. 35. Additionally, FIG. 42 is a cross-sectional view taken along line B-B in FIG. 41, and FIG. 43 is a cross-sectional view taken along line D-D in FIG. 41. Herein, the constituent elements corresponding to the constituent elements shown in FIGS. 71, 72 and 73 are designated by the same reference numerals.

The coplanar line formed on the upper surface of the high-frequency substrate 40 according to Embodiment 6 is configured of the signal line 10 and the grounds which are formed in the same layer as the signal line 10 so as to interpose the signal line 10 therebetween. As the lower ground of the coplanar line, the plane-shaped grounds 50 are formed inside the high-frequency substrate 40. The grounds 20 of the coplanar line and the lower grounds 50 are mutually connected together via a plurality of conductive vias 30 which are aligned with predetermined intervals therebetween in the direction of transmitting signals through the coplanar line. The coaxial connector is configured of the outer conductor 70, the core line 80 serving as the inner conductor, and the dielectric member 90. At the joint section between the coplanar line and the coaxial connector, the signal line 10 is electrically connected to the core line 80 via conductive members 81 composed of solders or conductive bonds. Similarly, the grounds 20 are electrically connected to the outer conductor 70 via conductive members 71 composed of solders or conductive bonds.

The grounds 50 of the coplanar line are exposed in the opposite areas beside the signal line 10 on the terminal face of the high-frequency substrate 40 connected with the coaxial connector, wherein the exposed portions thereof are securely connected to the outer conductor 70 via the conductive members 60a, 60b composed of solders or conductive bonds.

Embodiment 6 has the same configuration as Embodiment 5 but adds the following modification. Projecting portions 70a, 70b are formed in the outer conductor 70 of the coaxial connector so as to interpose the core line 80 therebetween. The grounds 50, the outer conductor 70, and the projecting portions 70a, 70b are electrically connected together via the conductive members 60a, 60b. It is preferable that the grounds 50 and the conductive members 60a, 60b be bonded together entirely over the exposed area of the terminal face of the high-frequency substrate 40. It is preferable that the overall area for connecting the exposed portions of the grounds 50 and the outer conductor 70 via the a pair of the conductive member 60a and the projecting portion 70a and a pair of the conductive member 60b and the projecting portion 70b be formed continuously and upwardly from the extension line in the direction of transmitting signals through the coplanar line and be higher than the center position of the core line 80. Since the ground structure gradually varies in the direction from the grounds 50 to the outer conductor 70, it is possible to alleviate significant variations of electric field distribution at the joint section between the coplanar line and the coaxial connector when signals are transmitted from the coplanar line to the coaxial connector or from the coaxial connector to the coplanar line. In this connection, it is possible to employ an arbitrary shape as the joint section between the conductive member 60a and the projecting portion 70a and the joint section between the conductive member 60b and the projecting portion 70b in the direction of transmitting signals. For instance, it is possible to employ a rectangular shape (or a quadratic prism as a three-dimensional structure) as the joint section between the conductive member 60a and the projecting portion 70a as shown in FIG. 40; alternatively, it is possible to employ a triangular shape (or a wedge shape as a three-dimensional structure) as shown in FIG. 43.

It is preferable that the minimum distance dx between the exposed portions of the grounds 50 on the terminal face of the high-frequency substrate 40 be set to a desired value in response to the maximum frequency in a desired frequency range. That is, it is preferable that the minimum distance dx between the exposed portions of the grounds 50 be limited to less than a half wavelength of the maximum frequency of transmitting signals in consideration of a shortening coefficient of wavelength. Thus, it is possible to suppress electromagnetic emission due to half-wavelength resonance occurring between the exposed portions of the grounds 50. Specifically, it is necessary to satisfy Condition 1 (Equation 1) which limits the minimum distance dx to less than a half wavelength of the maximum frequency of transmitting signals in consideration of a shortening coefficient of wavelength in the dielectric layer 40b of the dielectric constant ∈b disposed just below the grounds 50, and Condition 2 (Equation 2) which limits the minimum distance dx to less than a half wavelength of the maximum frequency of transmitting signals in consideration of a shortening coefficient of wavelength in the dielectric layer 40a of the dielectric constant ∈a disposed just above the grounds 50.

When the grounds 50 are electrically connected to the outer conductor 70 via the conductive members 60a, 60b whilst dx, ∈a and ∈b are determined to satisfy Condition 1 and Condition 2 (Equation 1 and Equation 2), it is possible to suppress frequency components of transmitting signals leaked into the dielectric layer 40b from the clearance gap 10 between the grounds 50 and the outer conductor 70. Additionally, it is preferable that the minimum distance dy between the conductive members 60a and 60b be equal to or less than the minimum distance dx on the intersection line depicted between the outer conductor 70 and the extension line in the direction of transmitting signals through the grounds 50. Thus, it is possible to easily reproduce the interval between the conductive members 60a and 60b for connecting the grounds 50 and the outer conductor 70.

The grounds 50 of the coplanar line are exposed in the opposite areas beside the signal line 10 on the terminal face of the high-frequency substrate 40 in the high-frequency transmission line according to Embodiment 6, whereby it is possible to securely connect the exposed portions of the grounds 50 to the outer conductor 70 via the conductive members 60a, 60b. For this reason, even when the clearance gap 100 is formed between the grounds 50 and the outer conductor 70 due to manufacturing error, it is possible to suppress frequency components of transmitting signals leaked into the clearance gap 100 and to thereby reduce an insertion loss due to electromagnetic emission since the minimum distance dx between the exposed portions of the grounds 50 on the terminal face of the high-frequency substrate 40, the dielectric constant ∈a of the dielectric layer 40a, and the dielectric constant ∈b of the dielectric layer 40b are determined to satisfy Equation 1 and Equation 2.

The foregoing effect can be secured as long as the exposed portions of the grounds 50 are electrically connected to the outer conductor 70; hence, the exposed portions of the grounds 50 can be formed in an arbitrary shape. Additionally, it is possible to determine whether or not to apply plating to the dielectric faces of the exposed portions of the grounds 50.

Next, insertion loss characteristics of the high-frequency transmission line according to Embodiment 6 will be described.

The following numerical condition is adopted to verify insertion loss characteristics. The high-frequency substrate 40 is a multilayered wiring substrate composed of resins constituting the dielectric layer 40a of the dielectric constant 3.88 disposed above the grounds 50 and the dielectric layer 40b of the dielectric constant 4.85 disposed below the grounds 50. Herein, the thickness of the dielectric layer 40a is 250 [μm]; the width of the signal line 10 is 450 [μm]; the interval between the signal line 10 and the grounds 20 is 880 [μm]; the diameter of the conductive via 30 is 250 [μm]; and the interval between a plurality of conductive vias 30 aligned in the direction of transmitting signals is 500 [μm]. Additionally, the thickness of the signal line 10 and the thickness of the ground 20 are each set to 71 [μm]; the thickness of the ground 50 is 35 [μm]; the dielectric member 90 of the coaxial connector has a dielectric constant of 3.3, and the diameter of the dielectric member 90 is 1397 [μm]; and the diameter of the core line 80 is 300 [μm]. The exposed portions of the grounds 50 are formed in a semi-circular shape with a curvature radius of 400 [μm], and the minimum distance dx between the peripheries of the exposed portions of the grounds 50 is 1000 [μm]. Furthermore, the interval between the grounds 50 and the outer conductor 70 is 100 [μm], wherein they are electrically connected together although a clearance gap is formed therebetween.

The foregoing numerical condition is used to analyze a comparative example in which the grounds 50 having no exposed portions are not connected to the outer conductor 70, and Embodiment 6 in which the minimum distance dx between the exposed portions of the grounds 50 on the terminal face of the high-frequency substrate 40 is 1000 [μm] and in which the exposed portions of the grounds 50 are electrically connected to the outer conductor 70, thus making comparison therebetween with respect to insertion loss (|S₂₁|) characteristics. The analysis result is shown in FIG. 44. Herein, two characteristic curves are shown as Embodiment 6. That is, these curves are provided with respect to Embodiment 6A in which, as shown in FIGS. 35, 38 and 40, the exposed portions of the grounds 50 are electrically connected to the projecting portions 70a, 70b of the outer conductor 70 via the conductive members 60a, 60b and in which the overall height combining a pair of the conductive member 60a and the projecting portion 70a and a pair of the conductive member 60b and the projecting portion 70b is set to 321 [μm], and Embodiment 6B in which the overall height is set to 1199 [μm]. In this connection, a pair of the conductive member 60a and the projecting portion 70a and a pair of the conductive member 60b and the projecting portion 70b are each formed in a semicircular column shape. A graph of FIG. 44 shows that the comparative example indicates 0 to 16.5 GHz as the frequency range whose insertion loss is less than 1 dB, whilst Embodiment 6A indicates 0-47 GHz demonstrating an improvement of about 30 GHz, and Embodiment 6B indicates 0-60 GHz demonstrating an improvement of about 44 GHz.

### Embodiment 7

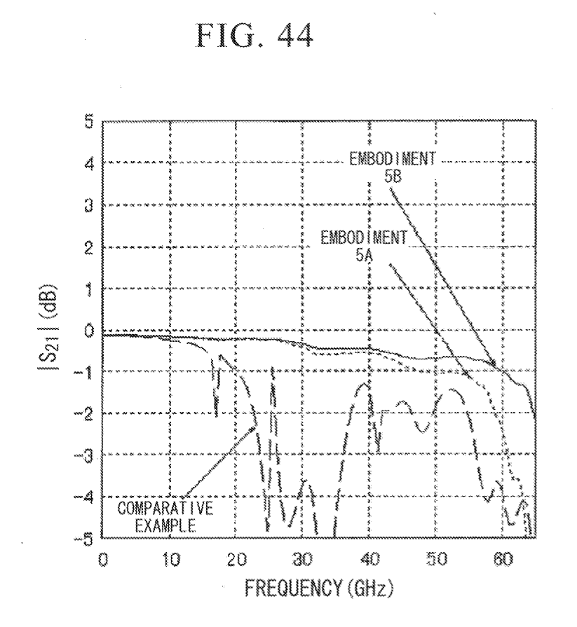

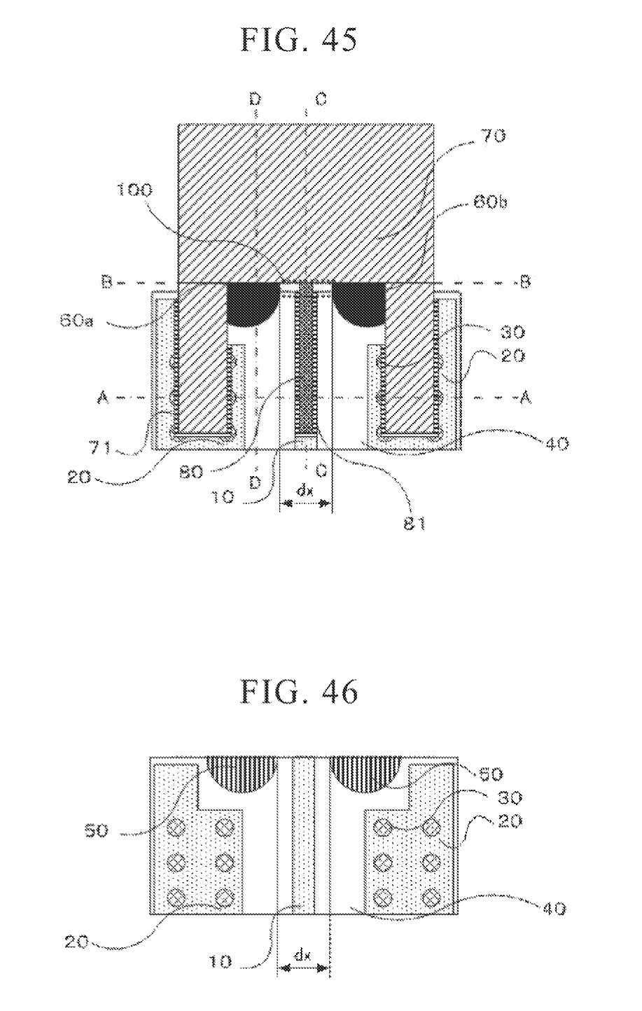

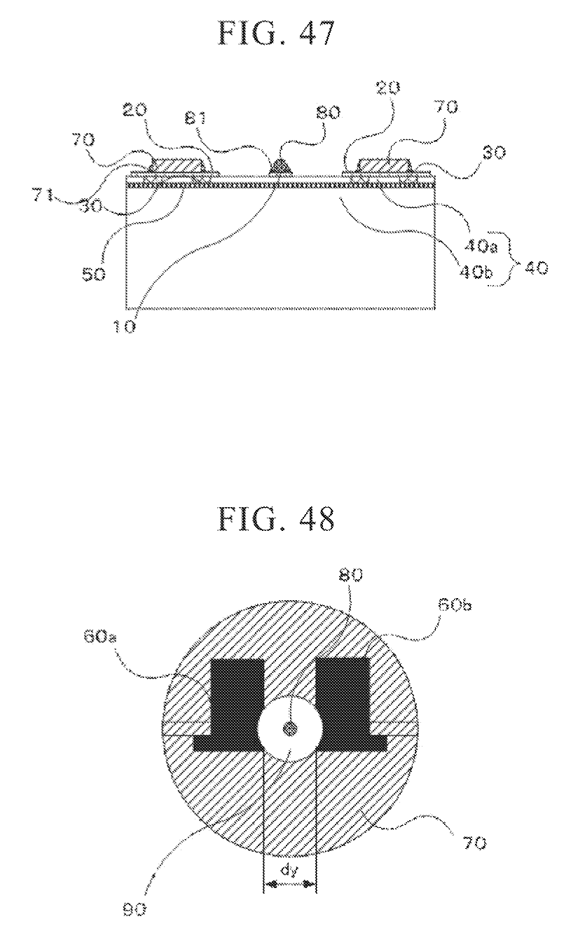

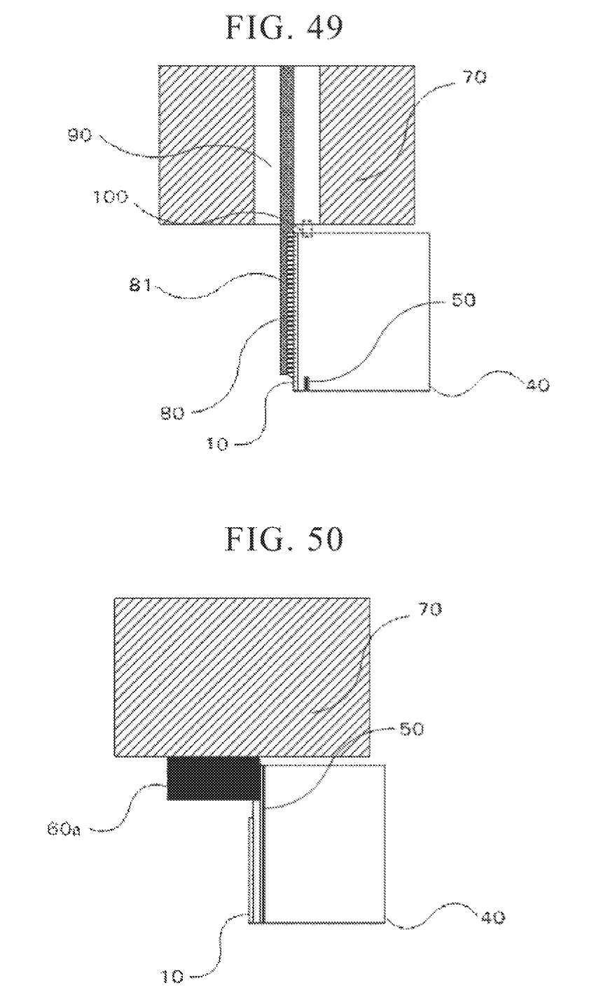

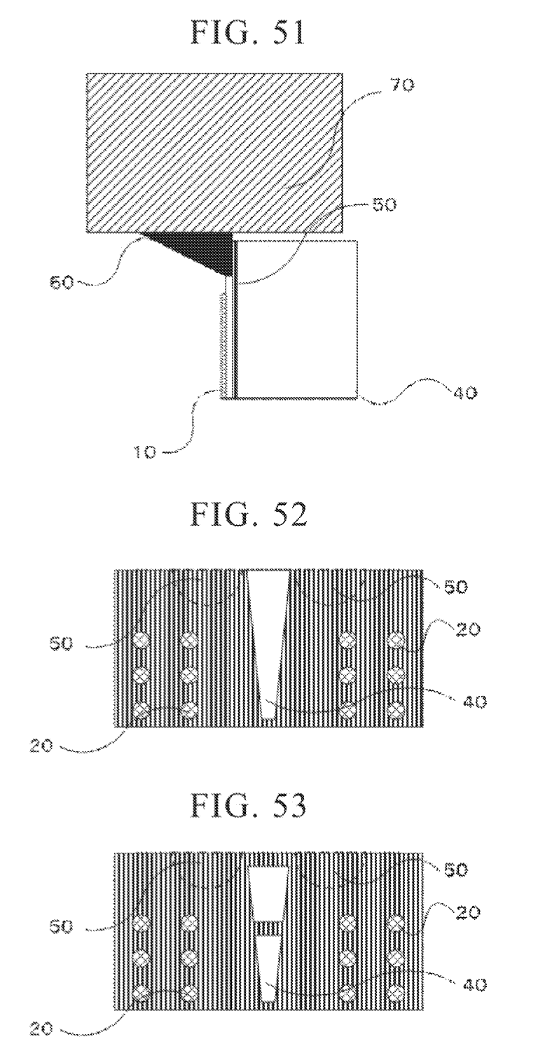

Next, a high-frequency transmission line and the high-frequency substrate 40 according to Embodiment 7 of this invention will be described with reference to FIGS. 45-56. FIG. 45 is a top view of the high-frequency transmission line and the high-frequency substrate 40 according to Embodiment 7; FIG. 46 is a top view showing the high-frequency substrate 40 alone; FIG. 47 is a cross-sectional view taken along line A-A in FIG. 45; FIG. 48 is a cross-sectional view taken along line B-B in FIG. 45; FIG. 49 is a cross-sectional view taken along line C-C in FIG. 45; FIGS. 50 and 51 are cross-sectional views taken along line D-D in FIG. 45. FIGS. 52-54 are top views showing variations of the grounds 50 shown in FIG. 46. Herein, the constituent elements corresponding to the constituent elements shown in FIGS. 71, 72 and 73 are designated by the same reference numerals.

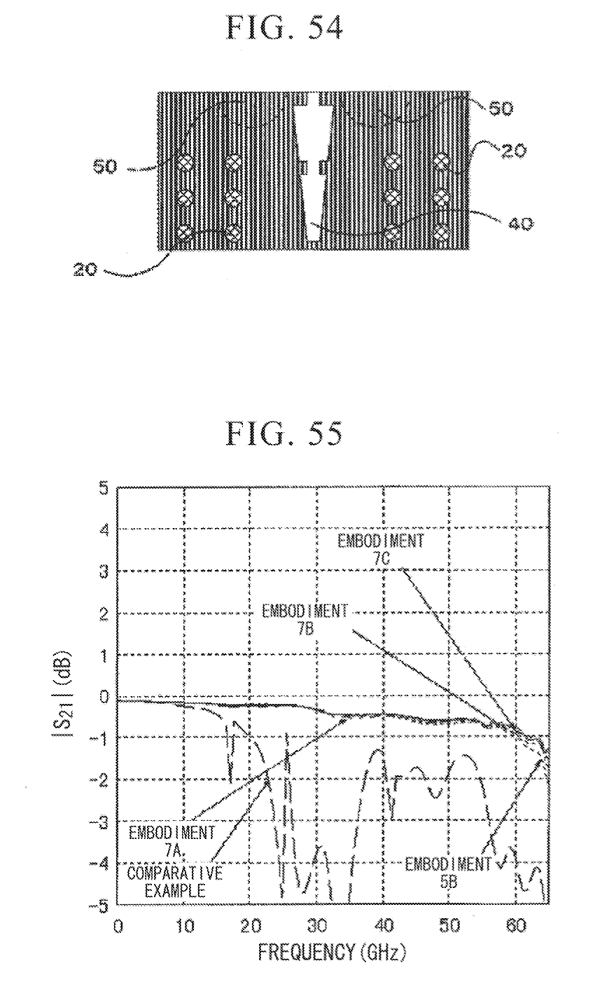

Embodiment 7 applies the following modification to Embodiment 5. As shown in FIG. 52, a cutout having a trapezoidal shape or a triangular shape is formed in the exposed portions of the grounds 50 on the terminal face of the high-frequency substrate 40. It is preferable that the length of this cutout be identical to the length of the core line 80 of the coaxial connector overlapped with the signal line 10 in the direction of transmitting signals. Since the ground structure gradually varies in the direction from the lower grounds 50 of the coplanar line to the outer conductor 70 of the coaxial connector, it is possible to alleviate significant variations of electric field distribution at the joint section between the coplanar line and the coaxial connector when signals are transmitted from the coplanar line to the coaxial connector or from the coaxial connector to the coplanar line. In this connection, the cutout is not necessarily limited to a single trapezoidal region as shown in FIG. 52; hence, cutouts can be formed using a plurality of trapezoidal regions as shown in FIG. 53, in which oblique lines trapezoidal regions are aligned linearly. Alternatively, the cutout is configured of a plurality of trapezoidal regions as shown in FIG. 54, in which trapezoidal regions are partially interconnected together, and in which oblique lines of trapezoidal regions are aligned linearly. Thus, it is possible to improve reflection characteristics of the high-frequency substrate 40 in a higher frequency range without degrading reflection characteristics in an intermediate frequency range.

Next, insertion loss characteristics of the high-frequency transmission line according to Embodiment 7 will be described. The same numeral condition as Embodiment 5 is adopted to verify insertion loss characteristics. In the case of the grounds 50 shown in FIG. 52, a cutout is formed in a trapezoidal region whose lower edge matches the edge line of the high-frequency substrate (in which the length of an upper edge is 300 [μm]; the length of a lower edge is 756 [μm]; and the height is 1422 [μm]). In the case of the grounds 53 shown in FIG. 53, a trapezoidal region shown in FIG. 52 is divided at the position of 100 [μm] and at the position of 711 [μm] measured inwardly from the edge line of the high-frequency substrate, wherein an interval between divisions is set to 200 [μm]. That is, two trapezoidal cutouts are formed in the grounds 50 of FIG. 53. In the grounds 50 shown in FIG. 54, two rectangular cutouts each having a length of 200 [μm] and a width of 300 [μm] are formed at the position of 100 [μm] and at the position of 711 [μm], measured from the edge line of the high-frequency substrate, in connection with two trapezoidal regions shown in FIG. 53, so that two trapezoidal regions join together to form a polygonal cutout in the entire shape.

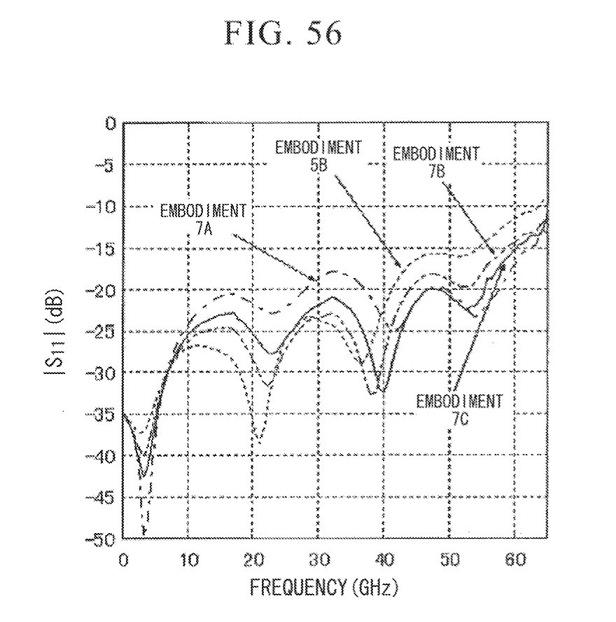

The foregoing numerical condition is adopted to analyze a comparative example in which the grounds 50 having no exposed portions are not connected to the outer conductor 70 of the coaxial connector, and Embodiment 5B in which the minimum distance dx between the exposed portions of the grounds 50 is set to 100 [μm], the exposed portions of the grounds 50 are electrically connected to the outer conductor 70 via the conductive members 60a, 60b each having a semi-circular column shape, and the height of the conductive members 60a, 60b above the grounds 50 is set to 1199 [μm], as well as Embodiment 7A, Embodiment 7B and Embodiment 7C which modify Embodiment 5 by forming the cutouts shown in FIGS. 51, 52 and 53 in the grounds 50, thus making comparison therebetween with respect to insertion loss (|S₂₁|) characteristics. The analysis result is shown in FIG. 55. Additionally, reflection (|S₂₁|) characteristics are compared among Embodiment 5B, Embodiment 7A, Embodiment 7B and Embodiment 7C. The analysis result is shown in FIG. 56.

FIG. 55 shows that the comparative example indicates 0 to 16.5 GHz as the frequency range whose insertion loss is less than 1 dB, whilst any one of Embodiments 7A-7C indicates 0 to 60 GHz demonstrating an improvement of about 44 GHz. FIG. 55 does not show a significant difference of insertion loss between Embodiment 5B and Embodiments 7A-7C. As to reflection characteristics shown in FIG. 56, Embodiment 5B indicates 0 to 54 GHz as the frequency range whose reflection value is less than −15 dB, whilst Embodiment 7A indicates 0 to 62 GHz demonstrating an improvement of about 8 GHz, Embodiment 7B indicates 0 to 58.5 GHz demonstrating an improvement of about 4.5 GHz, and Embodiment 7C indicates 0 to 60 GHz demonstrating an improvement of about 6 GHz.

### Embodiment 8

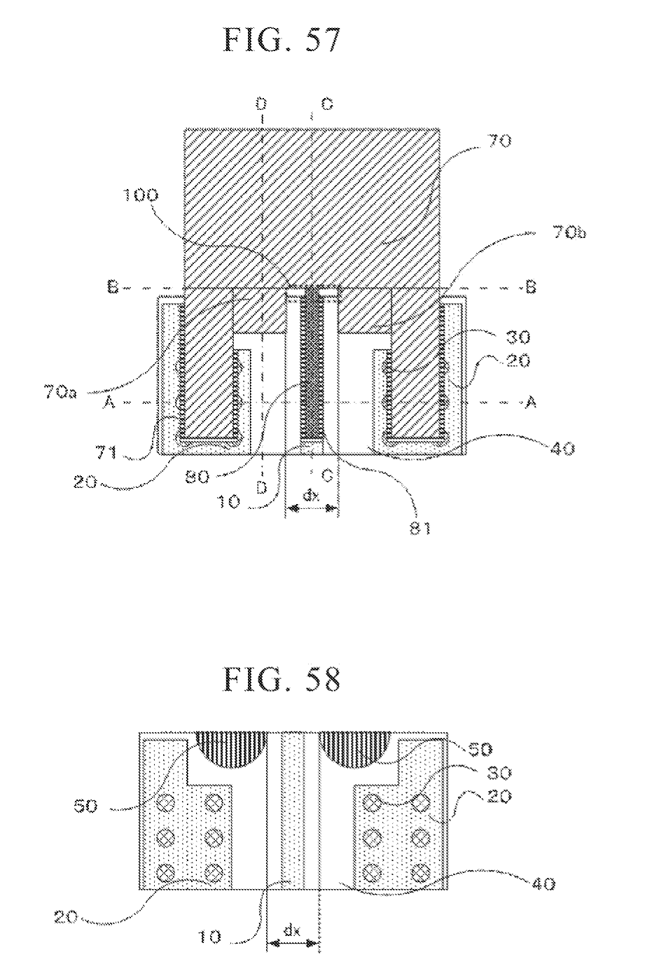

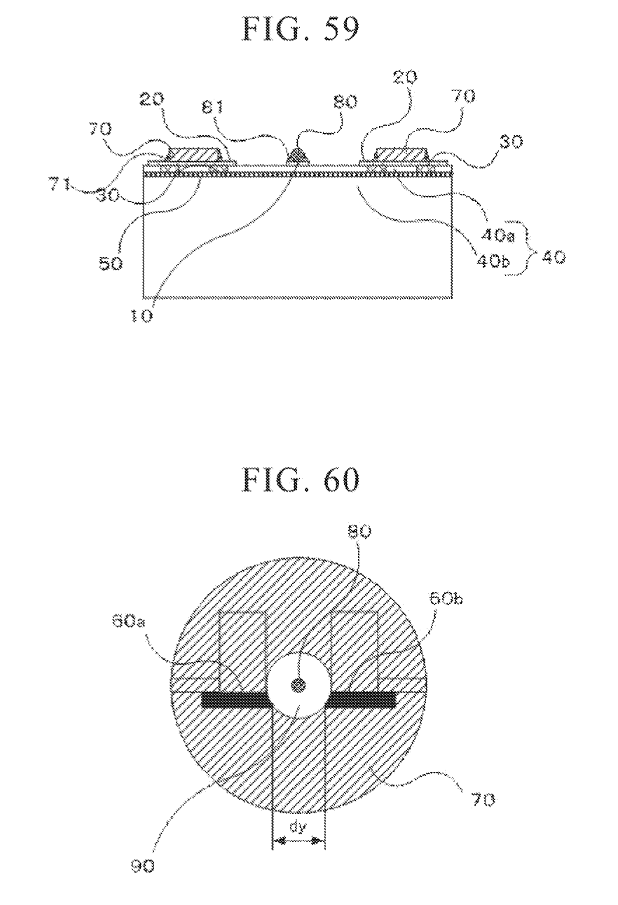

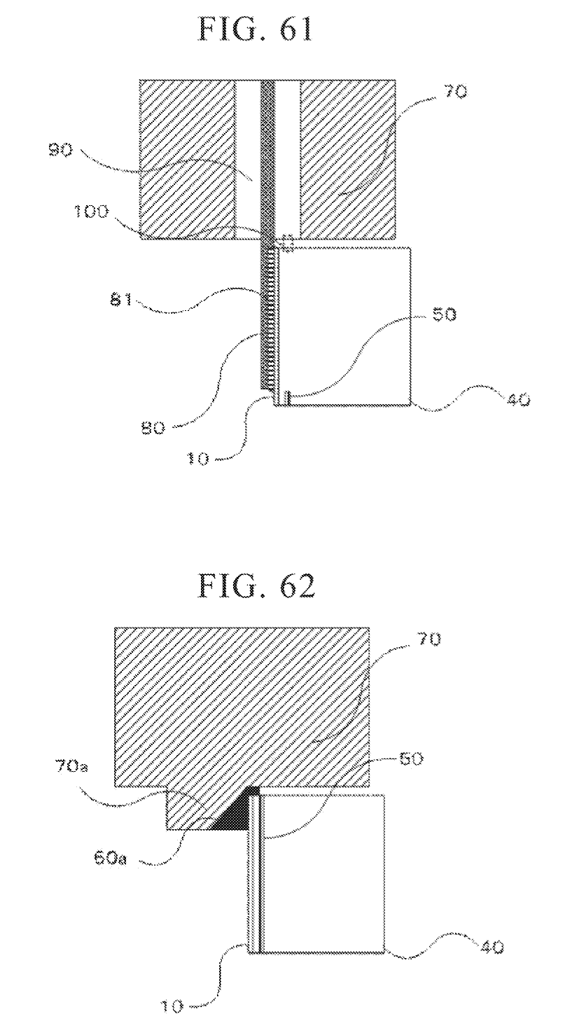

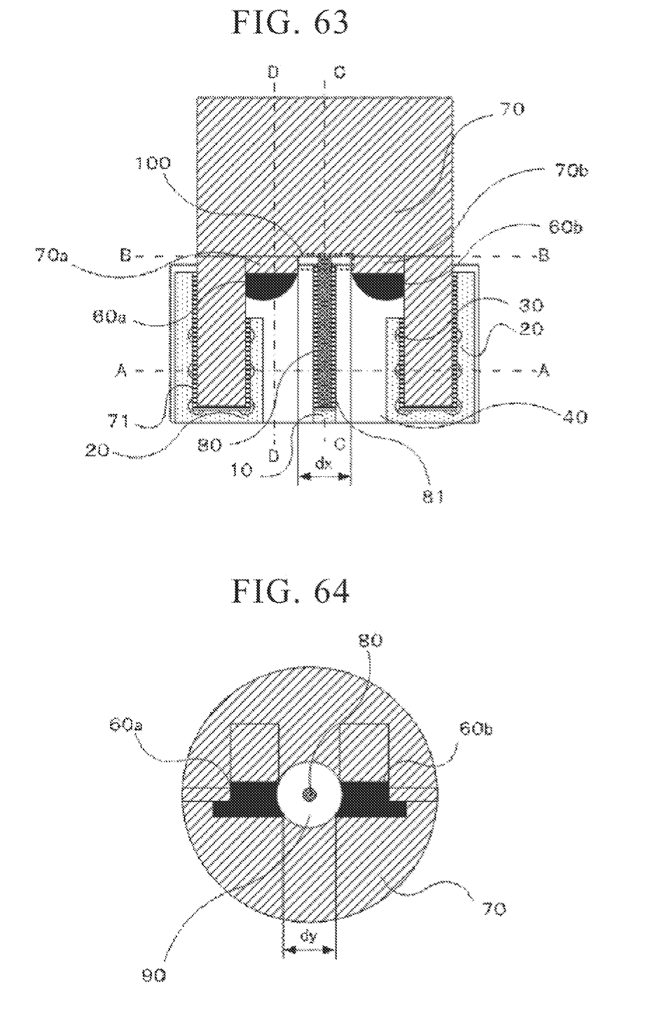

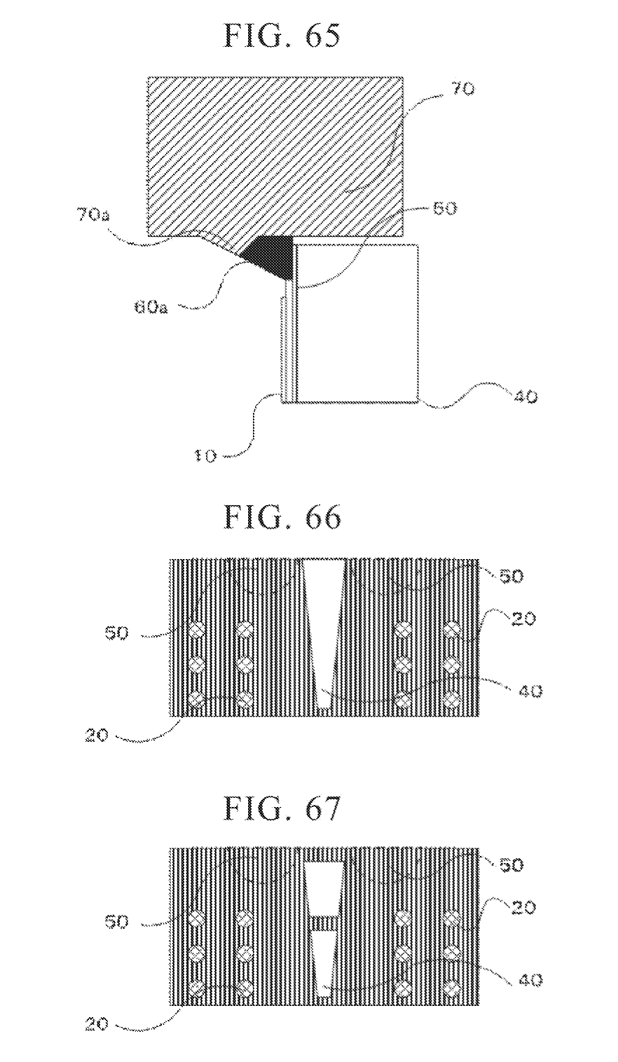

Next, a high-frequency transmission line and the high-frequency substrate 40 according to Embodiment 8 of this invention will be described with reference to FIGS. 57 to 70. FIGS. 57 and 63 are top views of the high-frequency transmission line and the high-frequency substrate 40 according to Embodiment 8; FIG. 58 is a top view of the high-frequency substrate 40; FIG. 59 is a cross-sectional view taken along line A-A in FIGS. 57 and 63; FIG. 60 is a cross-sectional view taken along line B-B in FIGS. 57 and 63; FIG. 61 is a cross-sectional view taken along line C-C in FIG. 57; FIG. 62 is a cross-sectional view taken along line D-D in FIG. 57; FIG. 64 is a cross-sectional view taken along line C-C in FIG. 63; and FIG. 65 is a cross-sectional view taken along line D-D in FIG. 63. FIGS. 66-68 are top views of the grounds 50 shown in FIG. 58. Herein, the constituent elements corresponding to the constituent elements shown in FIGS. 71, 72 and 73 are designated by the same reference numerals.

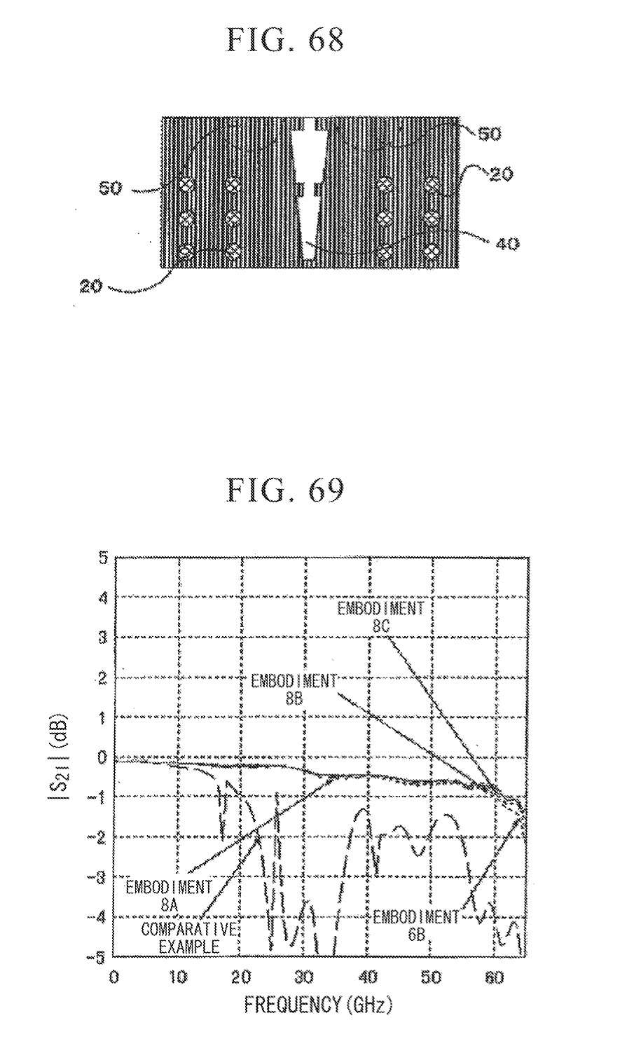

Embodiment 8 applies the following modification to Embodiment 6. As shown in FIG. 66, a cutout having a trapezoidal shape or a triangular shape, based on the edge line of the high-frequency substrate 40, is formed in the area interposed between the exposed portions of the grounds 50. It is preferable that the length of the cutout based on the edge line of the high-frequency substrate 40 be identical to the length of the coaxial line 80 of the coaxial connector overlapping with the signal line 10 in the direction of transmitting signals. Since the ground structure gradually varies from the lower grounds 50 of the coplanar line to the outer conductor 70 of the coaxial connector, it is possible to alleviate significant variations of electric field distribution in the joint section between the coplanar line and the coaxial connector when signals are transmitted from the coplanar line to the coaxial connector or from the coaxial connector to the coplanar line. In this connection, the cutout is not necessarily configured of a single trapezoidal region as shown in FIG. 66; hence, it is possible to form a plurality of trapezoidal regions shown in FIG. 67 in which oblique lines of trapezoidal regions are aligned linearly. Alternatively, it is possible to form two trapezoidal cutouts which are partially connected together and in which oblique lines are linearly aligned as shown in FIG. 68. Thus, it is possible to improve reflection characteristics of the high-frequency substrate 40 in a higher frequency range without degrading reflection characteristics in an intermediate frequency range.

Next, insertion loss characteristics of Embodiment 8 will be described. The same numerical condition as Embodiment 6 is adopted to verify insertion loss characteristics with respect to Embodiments 8A-8C which are designed based on the illustrations of FIGS. 66-68. In the case of Embodiment 8A based on the illustration of FIG. 66, a cutout whose lower edge matches the edge line of the high-frequency substrate 40 (in which the length of an upper edge is 300 [μm]; the length of the lower edge is 756 [μm]; and the height is 1422 [μm]) is formed in the grounds 50. In the case of Embodiment 8B based on the illustration of FIG. 67, a trapezoidal cutout is divided into two trapezoidal sections at the position of 100 [μm] and at the position of 711 [μm], measured from the edge line of the high-frequency substrate 40, wherein an interval therebetween is set to 200 [μm]. In the case of Embodiment 8C based on the illustration of FIG. 68, two trapezoidal cutouts shown in FIG. 67 are connected together by means of two rectangular cutouts, each having a length of 200 [μm] and a width of 300 [μm], at the position of 100 [μm] and at the position of 711 [μm] measured from the edge line of the high-frequency substrate 40, thus forming a polygonal cutout.

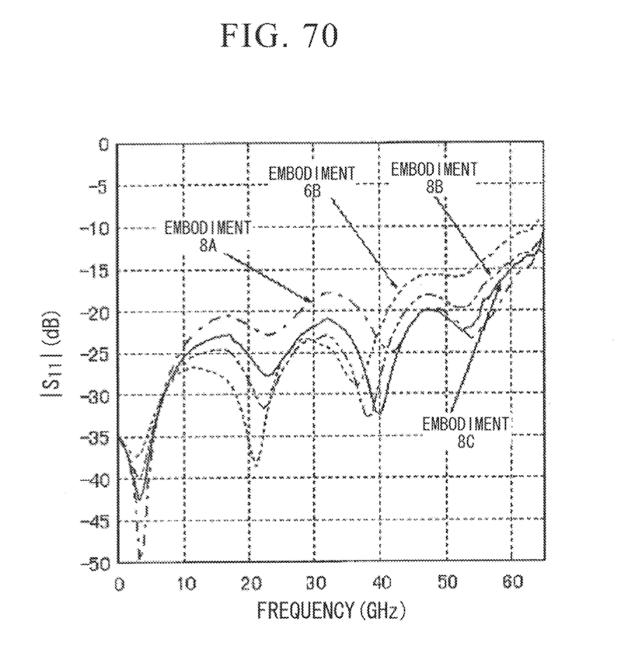

The foregoing numerical condition is adopted to analyze a comparative example in which the grounds 50 having no exposed portions are not connected to the outer conductor 70 of the coaxial connector, and Embodiment 6B in which the minimum distance dx between the exposed portions of the grounds 50 on the terminal face of the high-frequency substrate 40 is set to 1000 [μm], the exposed portions of the grounds 50 are electrically connected to the projecting portions 70a, 70b of the outer conductor 70 via the conductive members 60a, 60b, a pair of the conductive member 60a and the projecting portion 70a and a pair of the conductive member 60b and the projecting portion 70b are each formed in a semi-circular column shape, and the total height combining them above the grounds 50 is set to 1199 [μm], as well as Embodiments 8A-8C which modify Embodiment 6 such that the cutouts shown in FIGS. 66-68 are formed in the grounds 50 whose exposed portions are connected to the projecting portions 70a, 70b of the outer conductor 70, thus making comparison therebetween with respect to insertion loss (|S₂₁|) characteristics. The analysis result is shown in FIG. 69. Additionally, Embodiment 6B and Embodiments 8A-8C are compared with respect to reflection (|S₁₁|) characteristics. The analysis result is shown in FIG. 70.

FIG. 69 shows that the comparative example indicates 0 to 16.5 GHz as the frequency range whose insertion loss is less than 1 dB, whilst Embodiments 8A-8C indicate 0 to 60 GHz demonstrating an improvement of about 44 GHz. A significant difference of insertion loss can be found between Embodiment 6B and Embodiments 8A-8C. As to reflection characteristics, Embodiment 6B indicates 0 to 54 GHz as the frequency range whose reflection value is less than −15 dB, whilst Embodiment 8A indicates 0 to 62 GHz demonstrating an improvement of 8 GHz, Embodiment 8B indicates 0 to 58.5 GHz demonstrating an improvement of 4.5 GHz, and Embodiment 8C indicates 0 to 60 GHz demonstrating an improvement of 6 GHz.

The foregoing embodiments employ conductive vias as means for connecting different layers; but this is not a restriction. For instance, it is possible to employ other electric connecting means having conductivity such as through-holes. Additionally, the high-frequency substrates based on the foregoing embodiments can be incorporated into portable telephones, PDAs (Personal Digital Assistants), and other electronic devices.

As described above, the high-frequency substrate of this invention is not necessarily limited to the foregoing embodiments; hence, it is possible to apply various modifications within the scope of the technological concept as defined by the appended claims.

### INDUSTRIAL APPLICABILITY

The high-frequency module and substrate of this invention is able to prevent an insertion loss from increasing due to electromagnetic emission and reflection particularly in a high frequency range; hence, this invention can be applied to various electronic devices.

### DESCRIPTION OF THE REFERENCE NUMERALS

10 Signal line of coplanar line
20 Ground of coplanar line (first ground)
30 Conductive via
40 High-frequency substrate
40a Dielectric layer (first dielectric layer)
40b Dielectric layer (second dielectric layer)
45 Conductive layer
50 Lower ground of coplanar line (second ground, second conductive layer)
60a Conductive member
60b Conductive member
61a Conductive member
61b Conductive member
70 Outer conductor of coaxial connector
70a Projecting portion of outer conductor
70b Projecting portion of outer conductor
71 Conductive member
80 Core line of coaxial connector (inner conductor)
81 Conductive member
90 Dielectric member of coaxial connector
100 Clearance gap between lower ground and outer conductor
110 Conductive via

1. A high-frequency substrate including a coplanar line coupled with a coaxial connector, wherein said coplanar line further includes
a first dielectric layer,
a signal line that is formed on the surface of the first dielectric layer and connected to an inner conductor of the coaxial connector,
a first ground that is formed in opposite areas beside the signal line with a clearance distant from the signal line, and
a second ground that is formed on the backside of the first dielectric layer,
wherein a second dielectric layer is laminated with the first dielectric layer so as to interpose the second ground therebetween, and
wherein the second ground is exposed in a predetermined area of the first dielectric layer, so that the exposed portion of the second ground is connected to an outer conductor of the coaxial connector.

2. The high-frequency substrate according to claim 1, wherein the second ground is exposed in the opposite areas beside the signal line at a terminal face coupled with the coaxial connector in either the surface of the first dielectric layer or an opposite face opposite to a face of the second dielectric layer facing the first dielectric layer.

3. The high-frequency substrate according to claim 1, wherein a joint section between the exposed portion of the second ground and the outer conductor of the coaxial connector is a column-shaped region or a wedge-shaped region which is continuously formed along the surface of the outer conductor of the coaxial connector in a direction from the exposed portion of the second ground to the surface of the first dielectric layer.

4. The high-frequency substrate according to claim 3, wherein at least a part of the joint section, which is either the column-shaped region or the wedge-shaped region, between the exposed portion of the second ground and the outer conductor of the coaxial connector is configured of a projecting portion of the outer conductor of the coaxial connector.

5. The high-frequency substrate according to claim 3, wherein the height of the joint section, which is either the column-shaped region or the wedge-shaped region, measured in a direction toward the surface of the first dielectric layer from the exposed portion of the second ground is larger than a center height of the inner conductor of the coaxial connector.

6. The high-frequency substrate according to claim 1, wherein a minimum distance between the exposed portions of the second ground at the terminal face coupled with the coaxial connector is equal to or less than a half wavelength of a maximum frequency of transmitting signals in consideration of a shortening coefficient of wavelength.

7. The high-frequency substrate according to claim 1, wherein a minimum distance dx [μm] between the exposed portions of the second ground based on a dielectric constant ∈a of the first dielectric layer, a dielectric constant ∈b of the second dielectric layer, speed of light c [m/s], and a maximum frequency [GHz] of transmitting signals is determined to satisfy equations of
$$\begin{matrix}dx < \frac{c \times {10}^{- 3}}{2 \times f \times \sqrt{ɛ a}} \\ and & [ Equation 3 ] \\ dx < \frac{c \times {10}^{- 3}}{2 \times f \times \sqrt{ɛ b}} . & [ Equation 4 ]\end{matrix}$$

8. The high-frequency substrate according to claim 1, wherein a dielectric constant ∈a of the first dielectric layer and a dielectric constant ∈b of the second dielectric layer based on a minimum distance dx [μm] between the exposed portions of the second ground, speed of light c [m/s], and a maximum frequency [GHz] of transmitting signals are determined to satisfy equations of
$$\begin{matrix}dx < \frac{c \times {10}^{- 3}}{2 \times f \times \sqrt{ɛ a}} \\ and & [ Equation 5 ] \\ dx < \frac{c \times {10}^{- 3}}{2 \times f \times \sqrt{ɛ b}} . & [ Equation 6 ]\end{matrix}$$

9. The high-frequency substrate according to claim 2, wherein a cutout having a trapezoidal shape or a triangular shape is formed with a lower edge that matches a terminal edge of an area coupled with the coaxial connector and interposed between the exposed portions of the second ground.

10. The high-frequency substrate according to claim 2, wherein a plurality of trapezoidal cutouts is each independently formed based on a terminal edge of an area coupled with the coaxial connector and interposed between the exposed portions of the second ground such that oblique lines thereof are aligned linearly.

11. The high-frequency substrate according to claim 2, wherein a plurality of trapezoidal cutouts is each formed based on a terminal edge of an area coupled with the coaxial connector and interposed between the exposed portions of the second ground, and wherein the plurality of trapezoidal cutouts join together to form a polygonal cutout.

12. The high-frequency substrate according to claim 1, wherein at least one conductive via is formed to run through from the second ground to the second dielectric layer.

13. The high-frequency substrate according to claim 12, wherein the center of the conductive via is disposed on an intersection line between the second ground and a vertical line including a symmetrical line of the signal line.

14. The high-frequency substrate according to claim 1, wherein the first ground is connected to a pair of projecting portions interposing the inner conductor therebetween at a terminal face in which the inner conductor is extended from the outer conductor of the coaxial connector.

15. A high-frequency module including a high-frequency substrate having a coplanar line coupled with a coaxial connector, wherein said coplanar line further includes
a first dielectric layer,
a signal line that is formed on the surface of the first dielectric layer and connected to an inner conductor of the coaxial connector,
a first ground that is formed in opposite areas beside the signal line with a clearance distant from the signal line, and
a second ground that is formed on the backside of the first dielectric layer,
wherein a second dielectric layer is laminated with the first dielectric layer so as to interpose the second ground therebetween, and
wherein the second ground is exposed in a predetermined area of the first dielectric layer, so that the exposed portion of the second ground is connected to an outer conductor of the coaxial connector.

16. A manufacturing method of a high-frequency substrate including a coplanar line coupled with a coaxial connector, comprising:
sequentially forming a second conductive layer, a first dielectric layer, and a first conductive layer on a second dielectric layer;
selectively removing the first conductive layer and the first dielectric layer so as to expose a predetermined area of the second conductive layer;
selectively removing the first conductive layer so as to form a signal line coupled with the coaxial connector on the first dielectric layer; and
forming a ground on a terminal face coupled with the coaxial connector in opposite areas beside the signal line with a clearance distant from the signal line, thus forming the coplanar line including the signal line, the ground, and the second dielectric layer.

17. A manufacturing method of a high-frequency substrate including a coplanar line coupled with a coaxial connector, comprising:
sequentially forming a second conductive layer, a first dielectric layer, and a first conductive layer on a second dielectric layer;
selectively removing the second dielectric layer so as to expose the second conductive layer in opposite areas beside the signal line at a terminal face coupled with the coaxial connector;
selectively removing the first conductive layer so as to form a signal line coupled with an inner conductor of the coaxial connector on the first dielectric layer; and
forming a ground in the opposite areas beside the signal line with a clearance distant from the signal line, thus forming the coplanar line including the signal line, the second conductive layer, and the ground.
